(19) United States
(12) Patent Application Publication
(10) Pub. No.: US 2025/0169225 A1
(43) Pub. Date: May 22, 2025

(54) SOLID-STATE IMAGING DEVICE AND METHOD FOR MANUFACTURING THE SAME

(71) Applicant: SONY SEMICONDUCTOR SOLUTIONS CORPORATION, KANAGAWA (JP)

(72) Inventor: NAO YOSHIMOTO, KANAGAWA (JP)

(21) Appl. No.: 18/841,324

(22) PCT Filed: Jan. 24, 2023
(86) PCT No.: PCT/JP2023/002033

§ 371 Date: Aug. 23, 2024

(30) Foreign Application Priority Data
Mar. 3, 2022 (JP) 2022-032661

(51) Int. Cl. H10F 77/70; H10F 39/00; H10F 39/18

(52) U.S. Cl. CPC H10F 77/703; H10F 39/014; H10F 39/024; H10F 39/8067; H10F 39/182

(57) ABSTRACT

Photoelectric conversion efficiency is to be increased. A solid-state imaging device includes: a semiconductor substrate including a first surface as a light receiving surface, and an uneven structure unit provided in the first surface; a photoelectric conversion unit that is provided in the semiconductor substrate, and performs photoelectric conversion to generate electric charge corresponding to an amount of received light; and a reflective portion that is provided in the semiconductor substrate so as to extend substantially parallel to the first surface, and reflects light that has passed through the first surface.

### TECHNICAL FIELD

Embodiments of the present disclosure relate to a solid-state imaging device and a method for manufacturing the solid-state imaging device.

### BACKGROUND ART

In a solid-state imaging device such as a back-illuminated complementary metal oxide semiconductor (CMOS) image sensor, an uneven structure (a moth-eye structure, for example) is provided on the incident surface of a semiconductor substrate in some cases (see Patent Documents 1 and 2). With the uneven structure, the optical path length can be made longer by inclination of incident light, for example, and the photoelectric conversion efficiency quantum efficiency (Qe) can be increased in some cases.

### CITATION LIST

### Patent Document

Patent Document 1: WO 2016/194654 A
Patent Document 2: WO 2017/126329 A

### SUMMARY OF THE INVENTION

### Problems to be Solved by the Invention

However, there are cases where the optical path length cannot be made long enough, and it is difficult to increase the photoelectric conversion efficiency.

Therefore, the present disclosure provides a solid-state imaging device that can increase photoelectric conversion efficiency, and a method for manufacturing the solid-state imaging device.

### Solutions to Problems

To solve the above problem, the present disclosure provides
a solid-state imaging device that includes:
a semiconductor substrate including a first surface as a light receiving surface, and an uneven structure unit provided in the first surface;
a photoelectric conversion unit that is provided in the semiconductor substrate, and performs photoelectric conversion to generate electric charge corresponding to an amount of received light; and
a reflective portion that is provided in the semiconductor substrate so as to extend substantially parallel to the first surface, and reflects light that has passed through the first surface.

The uneven structure unit may include a plurality of protrusions or a plurality of recesses, and

the protrusions or the recesses may have a substantially polygonal outer shape as viewed from the normal direction of the first surface.

At least one side of the outer shape of the protrusion or the recess as viewed from the normal direction may be inclined with respect to the pixel array direction.

The protrusion or the recess may have a shape of a substantially quadrangular pyramid, and

the four sides of the outer shape of the protrusion or the recess as viewed from the normal direction may be inclined by 45° with respect to the pixel array direction.

The protrusion or the recess may have a shape of a substantially hexagonal pyramid.

The pixel array direction may be a direction in which an element isolating portion that isolates a plurality of pixels extend.

The semiconductor substrate may be a silicon substrate,
the uneven structure unit may have an inclined surface that is inclined with respect to the first surface, and
the inclined surface may be a silicon crystal plane of a plane index (111).

The solid-state imaging device according to claim 7, wherein an inclination angle of the inclined surface with respect to the first surface is not greater than 90°.

A plurality of the protrusions or a plurality of the recesses may be arranged to bring the protrusions or the recesses into contact with each other, as viewed from the normal direction.

A plurality of the protrusions or a plurality of the recesses may be arranged at intervals as viewed from the normal direction.

The material of the reflective portion may be a metal material or a material containing carbon (C).

The solid-state imaging device may further include:
a charge retaining unit that is disposed in the normal direction of the first surface with respect to the photoelectric conversion unit, and retains the electric charge transferred from the photoelectric conversion unit; and
a transfer transistor that transfers the electric charge generated by the photoelectric conversion unit, from the photoelectric conversion unit to the charge retaining unit,
in which the reflective portion may include a first reflective portion that is disposed to overlap the transfer transistor, and is provided to extend substantially parallel to the first surface, as viewed from the normal direction.

The solid-state imaging device may further include:
a charge retaining unit that is disposed in the normal direction of the first surface with respect to the photoelectric conversion unit, and retains the electric charge transferred from the photoelectric conversion unit; and
a transfer transistor that transfers the electric charge generated by the photoelectric conversion unit, from the photoelectric conversion unit to the charge retaining unit,
in which the reflective portion may include a second reflective portion that is disposed at a position different from the transfer transistor, and is provided to extend substantially parallel to the first surface, as viewed from the normal direction.

The solid-state imaging device may further include
a charge retaining unit that is disposed in the normal direction of the first surface with respect to the photoelectric conversion unit, and retains the electric charge transferred from the photoelectric conversion unit,
in which the reflective portion may include a third reflective portion that is disposed between the photoelectric conversion unit and the charge retaining unit, and is provided so as to extend substantially parallel to the first surface.

The present disclosure provides a method for manufacturing a solid-state imaging device, the method including:
forming a photoelectric conversion unit in a semiconductor substrate having a first surface as a light receiving surface, the photoelectric conversion unit being configured to perform photoelectric conversion to generate electric charge corresponding the amount of received light; and
forming a reflective portion that is provided in the semiconductor substrate so as to extend substantially parallel to the first surface and reflects light that has passed through the first surface, and forming an uneven structure unit in the first surface.

The forming the uneven structure unit may include:
forming a first mask material on the first surface;
forming a second mask material on the first mask material;
forming, in the second mask material, a pattern having at least one trench inclined with respect to a pixel array direction, as viewed from a normal direction of the first surface;
processing the first mask material and the semiconductor substrate, using the second mask material as a mask; and
processing the semiconductor substrate, using the first mask material as a mask.

### BRIEF DESCRIPTION OF DRAWINGS

FIG. 1 is a block diagram illustrating a schematic configuration of an imaging device according to an embodiment.

FIG. 2 is an equivalent circuit diagram of a sensor pixel and a readout circuit.

FIG. 3 is a planar layout diagram illustrating some pixel regions in a pixel array unit.

FIG. 4 is a cross-sectional view taken along the line A-A defined in FIG. 3.

FIG. 5A is a plan view of vertical light blocking portions of a second light blocking unit.

FIG. 5B is a plan view of a horizontal light blocking portion of the second light blocking unit.

FIG. 6A is a cross-sectional view of vertical light blocking portions of a first light blocking unit and second element isolating portions.

FIG. 6B is a cross-sectional view of horizontal light blocking portions of the first light blocking unit.

FIG. 7 is a plan view illustrating an example of the configuration of an uneven structure unit according to a first embodiment.

FIG. 8 is a plan view illustrating two examples of configurations of recesses according to the first embodiment.

FIG. 9A is a process drawing illustrating a method for manufacturing an imaging device according to the first embodiment.

FIG. 9B is a process drawing subsequent to FIG. 9A.

FIG. 9C is a process drawing subsequent to FIG. 9B.

FIG. 9D is a process drawing subsequent to FIG. 9C.

FIG. 9E is a process drawing subsequent to FIG. 9D.

FIG. 10 is a plan view illustrating an example of the configuration of an uneven structure unit according to a modification of the first embodiment.

FIG. 11A is a process drawing illustrating a method for manufacturing an imaging device according to the modification of the first embodiment.

FIG. 11B is a process drawing subsequent to FIG. 11A.

FIG. 11C is a process drawing subsequent to FIG. 11B.

FIG. 11D is a process drawing subsequent to FIG. 11C.

FIG. 11E is a process drawing subsequent to FIG. 11D.

FIG. 12 is a plan view illustrating an example of the configuration of an uneven structure unit according to a second embodiment.

FIG. 13 is a plan view illustrating an example of the configuration of an uneven structure unit according to a third embodiment.

FIG. 14 is a plan view illustrating two examples of configurations of recesses according to the third embodiment.

FIG. 15 is a process drawing illustrating a method for manufacturing an imaging device according to the third embodiment.

FIG. 16 is a plan view illustrating an example of the configuration of an uneven structure unit according to a fourth embodiment.

FIG. 17 is a plan view illustrating an example of the configuration of an uneven structure unit according to a fifth embodiment.

FIG. 18 is a plan view illustrating an example of the configuration of an uneven structure unit according to the fifth embodiment.

FIG. 19 is a plan view illustrating an example of the configuration of an uneven structure unit according to the fifth embodiment.

FIG. 20 is a plan view illustrating an example of the configuration of an uneven structure unit according to the fifth embodiment.

FIG. 21 is a cross-sectional view illustrating an example of the configuration of an imaging device according to a sixth embodiment.

FIG. 22 is a cross-sectional view illustrating an example of the configuration of an imaging device according to a seventh embodiment.

FIG. 23 is a cross-sectional view illustrating an example of the configuration of an imaging device according to an eighth embodiment.

FIG. 24 is a cross-sectional view illustrating an example of the configuration of an imaging device according to a ninth embodiment.

FIG. 25 is a cross-sectional view illustrating an example of the configuration of an imaging device according to a tenth embodiment.

FIG. 26 is a cross-sectional view illustrating an example of the configuration of an imaging device according to an eleventh embodiment.

FIG. 27 is a cross-sectional view illustrating an example of the configuration of an imaging device according to a twelfth embodiment.

FIG. 28 is a cross-sectional view illustrating an example of the configuration of an imaging device according to a thirteenth embodiment.

FIG. 29 is a cross-sectional view illustrating an example of the configuration of an imaging device according to a fourteenth embodiment.

FIG. 30 is a cross-sectional view illustrating an example of the configuration of an imaging device according to a fifteenth embodiment.

FIG. 31 is a cross-sectional view illustrating an example of the configuration of an imaging device according to a sixteenth embodiment.

FIG. 32 is a cross-sectional view illustrating an example of the configuration of an imaging device according to a seventeenth embodiment.

FIG. 33 is a cross-sectional view illustrating an example of the configuration of an imaging device according to an eighteenth embodiment.

FIG. 34 is a cross-sectional view illustrating an example of the configuration of an imaging device according to a nineteenth embodiment.

FIG. 35 is a cross-sectional view illustrating an example of the configuration of an imaging device according to a twentieth embodiment.

FIG. 36 is a cross-sectional view illustrating an example of the configuration of an imaging device according to a twenty-first embodiment.

FIG. 37 is a cross-sectional view illustrating an example of the configuration of an imaging device according to a twenty-second embodiment.

FIG. 38 is a cross-sectional view illustrating an example of the configuration of an imaging device according to a twenty-third embodiment.

FIG. 39 is a cross-sectional view illustrating an example of the configuration of an imaging device according to a twenty-fourth embodiment.

FIG. 40 is a cross-sectional view illustrating an example of the configuration of an imaging device according to a twenty-fifth embodiment.

FIG. 41 is a cross-sectional view illustrating an example of the configuration of an imaging device according to a twenty-sixth embodiment.

FIG. 42 is a cross-sectional view illustrating an example of the configuration of an imaging device according to a twenty-seventh embodiment.

FIG. 43 is a cross-sectional view illustrating an example of the configuration of an imaging device according to a twenty-eighth embodiment.

FIG. 44 is a cross-sectional view illustrating an example of the configuration of an imaging device according to a twenty-ninth embodiment.

FIG. 45 is a cross-sectional view illustrating an example of the configuration of an imaging device according to a thirtieth embodiment.

FIG. 46 is a cross-sectional view illustrating an example of the configuration of an imaging device according to a thirty-first embodiment.

FIG. 47 is a schematic diagram for explaining an off angle on the front surface of a Si substrate of the present disclosure.

FIG. 48 is a block diagram illustrating an example of a schematic configuration of a vehicle control system.

FIG. 49 is a block diagram illustrating an example of a schematic configuration of a vehicle control system.

FIG. 50 is an explanatory diagram illustrating an example of installation positions of an outside-vehicle information detection section and imaging sections.

FIG. 51 is a diagram illustrating an example of a schematic configuration of an endoscopic surgery system.

FIG. 52 is a block diagram illustrating an example of functional configurations of a camera head and a camera control unit (CCU).

### MODE FOR CARRYING OUT THE INVENTION

The following is a description of embodiments of a solid-state imaging device and a method for manufacturing the solid-state imaging device, with reference to the drawings. Although principal components of a solid-state imaging element and a method for manufacturing the solid-state imaging device will be mainly described below, the solid-state imaging device and the manufacturing method may include components and functions that are not illustrated or described. The following description does not exclude components and functions that are not illustrated or described.

### First Embodiment

In the description below, embodiments of the present disclosure will be described in detail. An imaging device of the present disclosure is a global-shutter back-illuminated image sensor such as a complementary metal oxide semiconductor (CMOS) image sensor, for example. The imaging device of the present disclosure receives light from the subject pixel by pixel, photoelectrically converts the light, and generates a pixel signal that is an electrical signal.

The global shutter method is a method of simultaneously starting and ending exposure of all pixels. Here, “all pixels” means all the pixels that form an effective image, and dummy pixels and the like that do not contribute to image formation are excluded. Further, if image distortion and the exposure time difference are sufficiently small so as not to cause any problem, the exposure does not necessarily have to be simultaneous. For example, the global shutter method also includes a case where the operation of performing simultaneous exposure in units of a plurality of rows (such as several tens of rows) is repeated while being shifted in units of a plurality of rows in the row direction. Further, the global shutter method also includes a case where simultaneous exposure is performed only for some pixel regions.

A back-illuminated image sensor is an image sensor in which a photoelectric conversion unit such as a photodiode that receives light from the subject and converts the light into an electrical signal is provided for each pixel between the light receiving surface on which light from the subject is incident and a wiring layer including wiring lines of a transistor or the like that drives each pixel. Note that the present disclosure can be applied to an image sensor of an imaging system other than a CMOS image sensor in some cases.

### (Block Configuration of an Imaging Device 101)

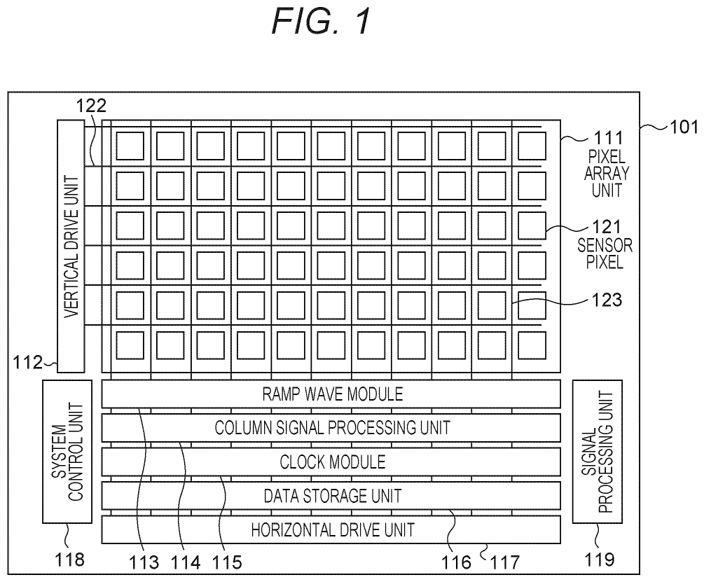

FIG. 1 is a block diagram illustrating a schematic configuration of an imaging device 101 according to an embodiment of the present disclosure. Formed on a semiconductor substrate 11, the imaging device 101 in FIG. 1 is, to be precise, a solid-state imaging device 101, but will be hereinafter referred to simply as the imaging device 101. The imaging device 101 in FIG. 1 includes a pixel array unit 111 in which a plurality of sensor pixels 121 that perform photoelectric conversion is arranged in a matrix that is a two-dimensional plane. The sensor pixels 121 corresponds to a specific example of “pixels” of the present disclosure. Pixel signals photoelectrically converted by the pixel array unit 111 are read out via a readout circuit.

The imaging device 101 includes the pixel array unit 111, a vertical drive unit 112, a ramp wave module 113, a column signal processing unit 114, a clock module 115, a data storage unit 116, a horizontal drive unit 117, a system control unit 118, and a signal processing unit 119, for example.

The imaging device 101 includes a single or a plurality of semiconductor substrates 11. For example, the imaging device 101 can be formed by electrically connecting another semiconductor substrate 11 on which the vertical drive unit 112, the ramp wave module 113, the column signal processing unit 114, the clock module 115, the data storage unit 116, the horizontal drive unit 117, the system control unit 118, the signal processing unit 119, and the like are formed by Cu—Cu bonding or the like to the semiconductor substrate 11 on which the pixel array unit 111 is formed.

The pixel array unit 111 includes a plurality of the sensor pixels 121 each including a photoelectric conversion element that generates and accumulates charge corresponding to the amount of light that has entered from the subject. As illustrated in FIG. 1, the sensor pixels 121 are arranged in the horizontal direction (row direction) and the vertical direction (column direction). In the pixel array unit 111, a pixel drive line 122 is provided in the row direction for each pixel row formed with the sensor pixels 121 arrayed in one line in the row direction, and a vertical signal line 123 is provided in the column direction for each pixel column formed with the sensor pixels 121 arrayed in one line in the column direction.

The vertical drive unit 112 includes a shift register, an address decoder, and the like. The vertical drive unit 112 supplies a signal or the like to the plurality of sensor pixels 121 via a plurality of the pixel drive lines 122, to drive all of the plurality of sensor pixels 121 in the pixel array unit 111 at the same time or in units of pixel rows.

The ramp wave module 113 generates a ramp wave signal to be used for analog/digital (A/D) conversion of pixel signals, and supplies the ramp wave signal to the column signal processing unit 114. The column signal processing unit 114 includes a shift register, an address decoder, and the like, for example, and performs a denoising process, a correlated double sampling process, an A/D conversion process, and the like, to generate a pixel signal. The column signal processing unit 114 supplies the generated pixel signal to the signal processing unit 119.

The clock module 115 supplies a clock signal for operation to each component of the imaging device 101.

The horizontal drive unit 117 sequentially selects unit circuits corresponding to the pixel columns in the column signal processing unit 114. The selective scanning is performed by the horizontal drive unit 117 so that the pixel signals subjected to signal processing for each unit circuit in the column signal processing unit 114 are sequentially output to the signal processing unit 119.

The system control unit 118 includes a timing generator or the like that generates various timing signals. The system control unit 118 controls driving of the vertical drive unit 112, the ramp wave module 113, the column signal processing unit 114, the clock module 115, and the horizontal drive unit 117, on the basis of the timing signals generated by the timing generator.

The signal processing unit 119 performs signal processing such as arithmetic processing on pixel signals supplied from the column signal processing unit 114 while temporarily storing data in the data storage unit 116 as necessary, and outputs an image signal including the respective pixel signal.

### (Circuit Configuration of a Readout Circuit 120)

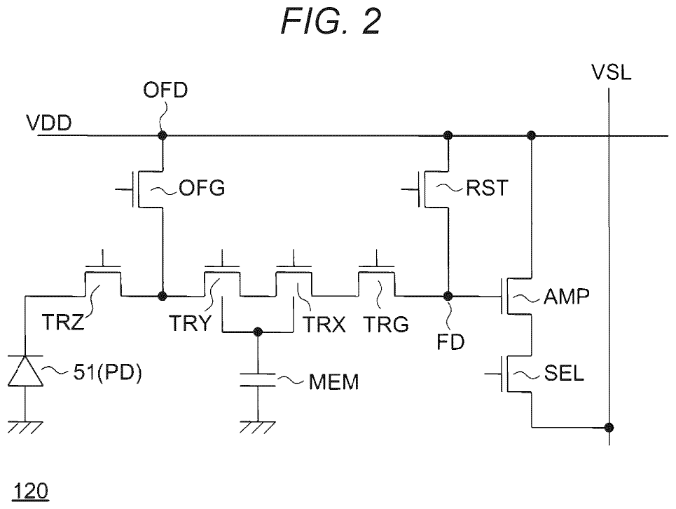

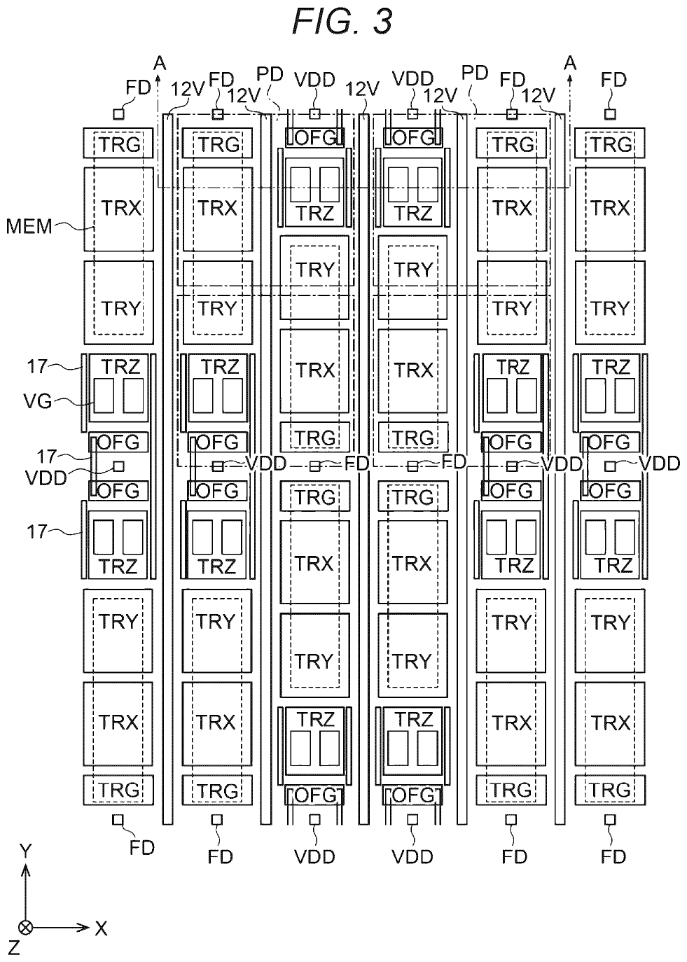

FIG. 2 is an equivalent circuit diagram of a sensor pixel 121 and a readout circuit 120. FIG. 3 is a planar layout diagram illustrating some pixel regions in the pixel array unit 111. FIG. 3 illustrates a planar layout of pixel regions of two pixels in the X direction and four pixels in the Y direction.

As illustrated in FIGS. 2 and 3, the readout circuit 120 includes four transfer transistors TRZ, TRY, TRX, and TRG, a discharge transistor OFG, a reset transistor RST, an amplification transistor AMP, and a select transistor SEL. These transistors are N-type MOS transistors. The reset transistor RST, the amplification transistor AMP, and the select transistor SEL are formed on a semiconductor substrate different from the semiconductor substrate 11 on which the pixel array unit 111 is disposed, and are then bonded to the semiconductor substrate 11. Therefore, these transistors are not clearly shown in the planar layout in FIG. 3.

In the description below, an example in which photodiodes PD are used as photoelectric conversion units 51 will be mainly described. The transfer transistor TRZ is connected to the photodiode PD in the sensor pixel 121, and transfers the electric charge (pixel signal) photoelectrically converted by the photodiode PD to the transfer transistor TRY. The transfer transistor TRZ is assumed to be a vertical transistor, and has a vertical gate electrode.

The transfer transistor TRY transfers the charge transferred from the transfer transistor TRZ, to the transfer transistor TRX. The transfer transistors TRY and TRX may be replaced with one transfer transistor. A charge retaining unit (MEM) 54 is connected to the transfer transistors TRY and TRX. The potential of the charge retaining unit (MEM) 54 is controlled by a control signal applied to the gate electrodes of the transfer transistors TRY and TRX. For example, when the transfer transistors TRY and TRX are turned on, the potential of the charge retaining unit (MEM) 54 becomes deeper. When the transfer transistors TRY and TRX are turned off, the potential of the charge retaining unit (MEM) 54 becomes shallower. Further, when the transfer transistors TRZ, TRY, and TRX are turned on, for example, the charge accumulated in the photodiode PD is transferred to the charge retaining unit (MEM) 54 via the transfer transistors TRZ, TRY, and TRX. The drain of the transfer transistor TRX is electrically connected to the source of the transfer transistor TRG, and the gates of the transfer transistors TRY and TRX are connected to the pixel drive line.

The charge retaining unit (MEM) 54 is a region that temporarily retains the charge accumulated in the photodiode PD, to achieve a global shutter function. The charge retaining unit (MEM) 54 retains the charge transferred from the photodiode PD.

The transfer transistor TRG is connected between the transfer transistor TRX and a floating diffusion FD, and transfers the charge held in the charge retaining unit (MEM) 54 to the floating diffusion FD, in accordance with a control signal applied to the gate electrode. For example, when the transfer transistor TRX is turned off, and the transfer transistor TRG is turned on, the charge retained in the charge retaining unit (MEM) 54 is transferred to the floating diffusion FD. The drain of the transfer transistor TRG is electrically connected to the floating diffusion FD, and the gate of the transfer transistor TRG is connected to the pixel drive line.

The floating diffusion FD is a floating diffusion region that temporarily retains the charge output from the photodiode PD via the transfer transistor TRG. The reset transistor RST is connected to the floating diffusion FD, and a vertical signal line VSL is also connected to the floating diffusion FD via the amplification transistor AMP and the select transistor SEL, for example.

The discharge transistor OFG initializes (resets) the photodiode PD, in accordance with a control signal applied to the gate electrode. The drain of the discharge transistor OFG is connected to a power supply line VDD, and the source is connected between the transfer transistor TRZ and the transfer transistor TRY.

When the transfer transistor TRZ and the discharge transistor OFG are turned on, for example, the potential of the photodiode PD is reset to the potential level of the power supply line VDD. That is, the photodiode PD is initialized. Also, the discharge transistor OFG forms an overflow path between the transfer transistor TRZ and the power supply line VDD, for example, and discharges the charge overflowing from the photodiode PD to the power supply line VDD.

The reset transistor RST initializes (resets) each of the regions from the charge retaining unit (MEM) 54 to the floating diffusion FD, in accordance with a control signal applied to the gate electrode. The reset transistor RST has the drain connected to the power supply line VDD, and the source connected to the floating diffusion FD. When the transfer transistor TRG and the reset transistor RST are turned on, for example, the potentials of the charge retaining unit (MEM) 54 and the floating diffusion FD are reset to the potential level of the power supply line VDD. That is, turning on the reset transistor RST initializes the charge retaining unit (MEM) 54 and the floating diffusion FD.

The amplification transistor AMP has the gate electrode connected to the floating diffusion FD and the drain connected to the power supply line VDD, and serves as an input unit of a source follower circuit that reads out the charge obtained by photoelectric conversion in the photodiode PD. That is, the amplification transistor AMP has the source connected to the vertical signal line VSL via the select transistor SEL, to form a source follower circuit with a constant current source connected to one end of the vertical signal line VSL.

The select transistor SEL is connected between the source of the amplification transistor AMP and the vertical signal line VSL, and a control signal is supplied as a select signal to the gate electrode of the select transistor SEL. When the control signal is turned on, the select transistor SEL enters a conductive state, and the sensor pixel 121 coupled to the select transistor SEL enters a selected state. As the sensor pixel 121 enters a selected state, the pixel signal output from the amplification transistor AMP is read out by a column signal processing circuit 22 via the vertical signal line VSL.

As illustrated in FIG. 3, the transfer transistors TRG, TRX, TRY, and TRZ in the readout circuit 120 of one sensor pixel 121, and the discharge transistor OFG are arranged in order in the Y direction. The respective transistors in two sensor pixels 121 adjacent in the Y direction are arranged symmetrically with respect to the boundary of the pixels in the Y direction. A case where the arrays of the respective transistors in the readout circuits 120 for two sensor pixels 121 adjacent in the X direction are reversed, and a case where the arrays are the same are alternately repeated.

The charge retaining unit (MEM) 54 is disposed below the transfer transistors TRG, TRX, and TRY. Further, the photodiode PD in one sensor pixel 121 is disposed over the regions below the transfer transistors TRG, TRX, and TRY of the sensor pixel 121 and the regions below the discharge transistor OFG and the transfer transistors TRZ and TRY of the sensor pixel 121 adjacent in the X direction.

The planar layout of the respective transistors in the readout circuit 120 is not limited to that illustrated in FIG. 3. When the layout of the respective transistors in the readout circuit 120 is changed, the locations of the photodiode PD and the charge retaining unit (MEM) 54 disposed below those transistors are also changed.

### (Cross-Section Structure of the Imaging Device 101)

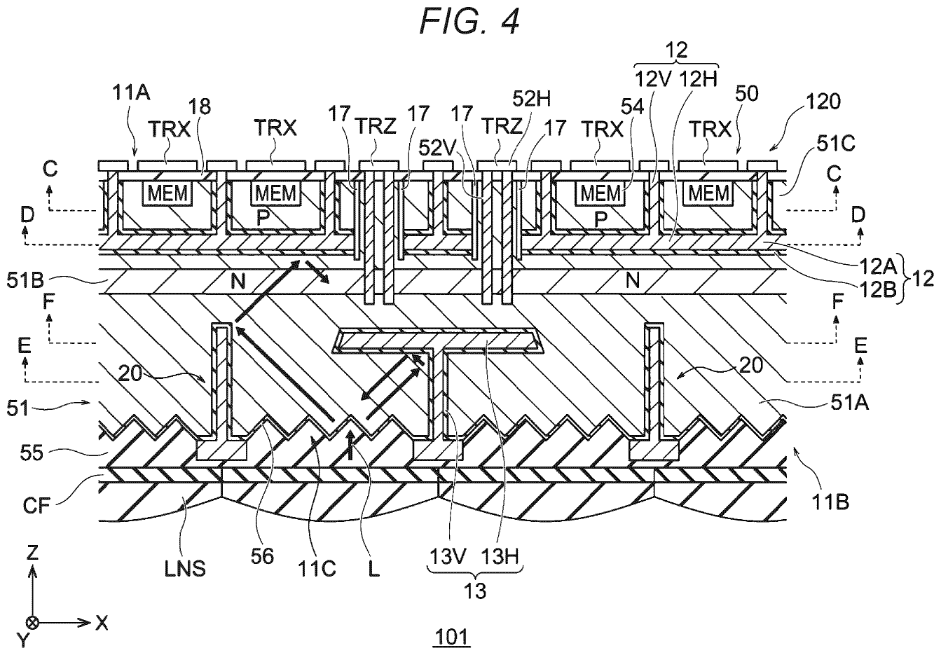

FIG. 4 is a cross-sectional view taken along the line A-A defined in FIG. 3. Symbols “P” and “N” in the drawing represent a P-type semiconductor region and an N-type semiconductor region, respectively. Further, “+” or “−” at the end of each symbol of “P++”, “P+”, “P−”, and “P−−” represents the impurity concentration of a P-type semiconductor region. Likewise, “+” or “−” at the end of each symbol of “N++”, “N+”, “N−”, and “N−−” represents the impurity concentration of an N-type semiconductor region. Here, a larger number of “+” indicates a higher impurity concentration, and a larger number of “−” indicates a lower impurity concentration. The same applies to the subsequent drawings.

The imaging device 101 illustrated in FIG. 4 includes the semiconductor substrate 11, photoelectric conversion units 51, charge retaining units (MEM) 54, a charge transfer unit 50, vertical gate electrodes 52V that are vertical electrodes of the transfer transistors TRZ, and a first light blocking unit 13.

The semiconductor substrate 11 is a single-crystal silicon substrate 11 having a crystal orientation of a plane index (111), for example. Hereinafter, the semiconductor substrate 11 will be sometimes referred to as the silicon (111) substrate. One of the reasons for using the silicon (111) substrate 11 is to include a step of performing wet etching in a direction parallel to the crystal plane as described later. Here, the plane index (111) is intended to include crystal orientations in which directions in three-dimensional directions are reversed, such as (−111), (1-11), and (11-1).

In addition to the above, the imaging device 101 includes a second light blocking unit 12, element isolating portions 13V and 20, etching stoppers 17, a film 56, color filters CF, and light receiving lenses LNS. In the present specification, of the semiconductor substrate 11, the one principal surface on the side where the light receiving lenses LNS are disposed is referred to as the back surface 11B or the light receiving surface, and the one principal surface on the side where the readout circuit 120 is disposed is referred to as the front surface 11A.

The photoelectric conversion units 51 in the semiconductor substrate 11 each include an N⁻-type semiconductor region 51A, an N-type semiconductor region 51B, and a P-type semiconductor region 51C, in order of closeness to the back surface 11B, for example. The light incident on the back surface 11B is photoelectrically converted in the N⁻-type semiconductor region 51A to generate charge, and the charge is accumulated in the N-type semiconductor region 51B. Note that the boundary between the N⁻-type semiconductor region 51A and the N-type semiconductor region 51B is not necessarily clear, and the N-type impurity concentration is only required to increase gradually in the direction from the N⁻-type semiconductor region 51A toward the N-type semiconductor region 51B, for example. Further, a P⁺-type semiconductor region having a higher P-type impurity concentration than that of the P-type semiconductor region 51C may be provided between the N-type semiconductor region and the P-type semiconductor region 51C. As described above, the layer configuration of the photoelectric conversion unit 51 formed in the semiconductor substrate 11 is not necessarily limited to that illustrated in FIG. 1.

The first light blocking unit 13 is disposed on a side closer to the back surface 11B of the semiconductor substrate 11 than the second light blocking unit 12. The first light blocking unit 13 includes vertical light blocking portions 13V extending in the depth direction of the semiconductor substrate 11, and horizontal light blocking portions 13H extending in the horizontal direction of the semiconductor substrate 11. The vertical light blocking portions 13V also serve as part of the element isolating portions 13V and 20 as described later. As illustrated in FIG. 4, the cross-sectional shape of the first light blocking unit 13 is a T-shape formed by the vertical light blocking portions 13V and the horizontal light blocking portions 13H. The horizontal light blocking portions 13H of the first light blocking unit 13 are disposed at positions overlapping the vertical gate electrodes 52V in the depth direction in a plan view. Because of this, light that has entered from the side of the back surface 11B of the semiconductor substrate 11 is blocked by the horizontal light blocking portions 13H, and is prevented from entering the vertical gate electrodes 52V. As described later, the first light blocking unit 13 excels in light reflection characteristics, and is sometimes referred to as a reflective member in the present specification.

The second light blocking unit 12 is a member that functions to prevent light from entering the charge retaining units (MEM) 54, and is provided so as to surround the charge retaining units (MEM) 54.

Specifically, the second light blocking unit 12 includes a horizontal light blocking portion 12H extending along a horizontal plane (X-Y plane) between the photoelectric conversion units 51 and the front surface 11A of the semiconductor substrate 11, and vertical light blocking portions 12V extending along the Y-Z plane so as to intersect with the horizontal light blocking portion 12H, for example. The second light blocking unit 12 excels in light reflection characteristics, and is sometimes referred to as a reflective member in the present specification.

The element isolating portions 13V and 20 are provided along the boundaries of the pixels, and include first element isolating portions 13V and second element isolating portions 20. The first element isolating portions 13V correspond to the vertical light blocking portions 13V of the first light blocking unit 13 described above. The second element isolating portions 20 are wall-like members that extend in the depth (Z-axis) direction along the boundary positions between the sensor pixels 121 adjacent to one another, and surround the respective photoelectric conversion units 51. The second element isolating portions 20 can electrically isolate the adjacent sensor pixels 121 from one another. The second element isolating portions 20 are formed with an insulating material such as silicon oxide, for example. The second element isolating portions 20 can be used for preventing light from entering the adjacent sensor pixels 121. The second element isolating portions 20 are formed with a material having excellent light absorption characteristics or reflection characteristics. Details of the second element isolating portions 20 will be described later.

As illustrated in FIG. 4, the vertical light blocking portions 13V (second element isolating portions 20) of the first light blocking unit 13 or the second element isolating portions 20 are disposed at the boundaries among the sensor pixels 121. In FIG. 4, the second element isolating portions 20 each have only a vertical light blocking portion. However, as will be described later, the second element isolating portions 20 may each include a vertical light blocking portion and a horizontal light blocking portion, and the cross-sectional shape of each second element isolating portion 20 may be any of various cross-sectional shapes such as the shape of the letter T or the shape of a cross.

Both of the vertical light blocking portions 13V of the first light blocking unit 13 and the second element isolating portions 20 can prevent light that has entered each sensor pixel 121 from the side of the back surface 11B of the semiconductor substrate 11 from leaking out to the adjacent sensor pixels 121, and thus, reduce inter-pixel crosstalk.

The first light blocking unit 13, the second light blocking unit 12, and the second element isolating portions 20 are not necessarily formed with the same structure and the same material, but are the same in containing a material that excels in light reflection characteristics. The first light blocking unit 13 and the second element isolating portions 20 each have a vertical light blocking portion extending in the depth direction from the side of the back surface 11B of the semiconductor substrate 11, while the second light blocking unit 12 has vertical light blocking portions extending in the depth direction from the side of the front surface 11A of the semiconductor substrate 11.

The respective gate electrodes of the transfer transistors TRZ, TRY, TRX, and TRG and the discharge transistor OFG in the readout circuit 120 are all provided on the side of the front surface 11A of the semiconductor substrate 11 via an insulating layer 18. Further, the charge retaining units (MEM) 54, which is N-type semiconductor regions, are provided in the P-type semiconductor region 51C in the semiconductor substrate 11. More specifically, the charge retaining units (MEM) 54 are disposed between the front surface 11A of the semiconductor substrate 11 and the horizontal light blocking portion 12H of the second light blocking unit 12. As illustrated in FIG. 4, the second light blocking unit 12 surrounds the charge retaining units (MEM) 54 so that light from the side of the back surface 11B does not enter the charge retaining units (MEM) 54. In the present specification, the transfer transistors TRZ, TRY, TRX, and TRG are collectively referred to as the charge transfer unit 50.

Each transfer transistor TRZ includes a horizontal gate electrode 52H disposed in the horizontal plane direction of the semiconductor substrate 11, and the vertical gate electrodes 52V extending in the depth direction of the semiconductor substrate 11. The deepest location of the vertical gate electrodes 52V is in the N⁻-type semiconductor region 52A, for example. Although each sensor pixel 121 has two vertical gate electrodes 52V in the example illustrated in FIG. 4, the number of vertical gate electrodes 52V is not limited, and may be one or plural. Each transfer transistor TRZ transfers the charge photoelectrically converted by the photoelectric conversion unit 51 to a transfer electrode TRY via the vertical gate electrode 52V.

As illustrated in FIG. 4, a planarizing film 55 is provided between the back surface 11B and the color filters CF. The planarizing film 55 is provided along the back surface 11B of the semiconductor substrate 11. The planarizing film 55 tightly connects the back surface 11B and the color filters CF.

As illustrated in FIG. 4, the color filters CF are disposed on the front surface of the planarizing film 55, and the light receiving lenses LNS are disposed on the front surfaces of the color filters CF. The color filters CF and the light receiving lenses LNS are provided for the respective pixels.

### (Structure of the Second Light Blocking Unit 12)

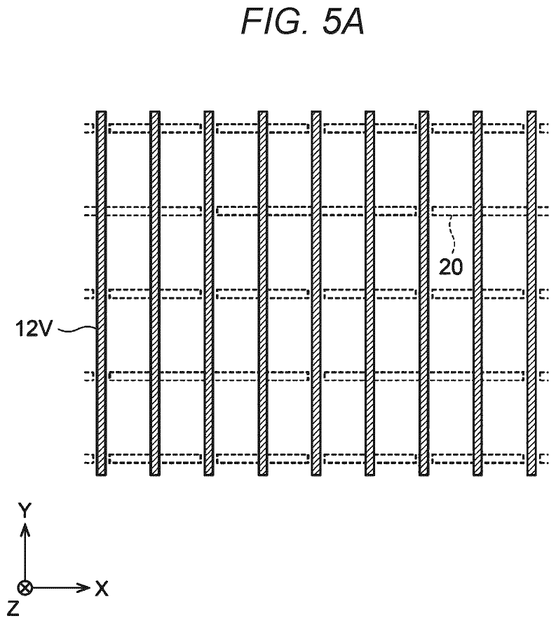

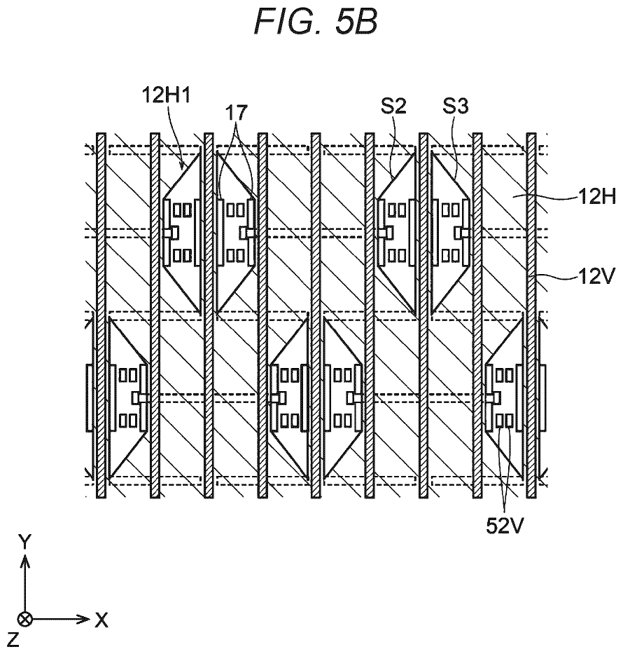

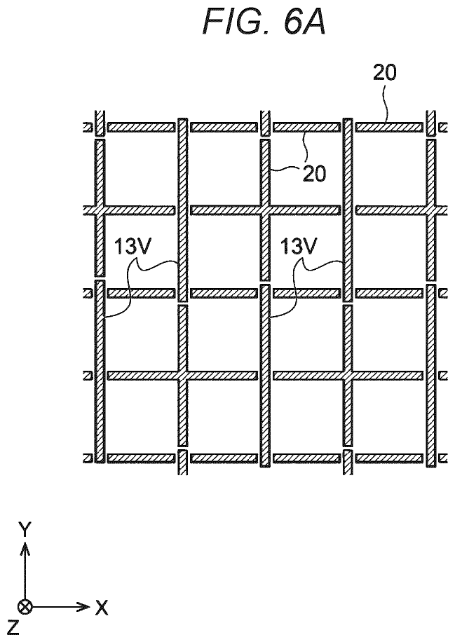

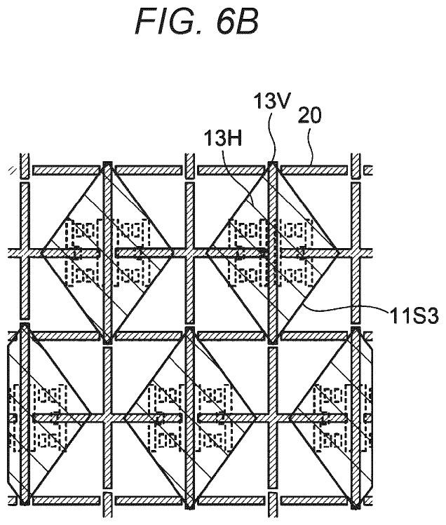

FIG. 5A is a plan view of the vertical light blocking portions 12V of the second light blocking unit 12. FIG. 5A is a plan view taken along the line C-C in FIG. 4. FIG. 5B is a plan view of the horizontal light blocking portion 12H of the second light blocking unit 12. FIG. 6B is a cross-sectional view taken along the line D-D defined in FIG. 4A. As illustrated in FIGS. 4 and 5A, the vertical light blocking portions 12V extend in the Y-axis direction along the boundary portions between the sensor pixels 121 adjacent to one another in the X-axis direction in a plan view, and along the substantial centers of the sensor pixels 121. The vertical light blocking portions 12V extend in the depth direction from the front surface 11A of the semiconductor substrate 11, and are connected to the horizontal light blocking portion 12H. The vertical light blocking portions 12V are arranged at intervals of a substantially half pixel in the X-axis direction, and have a length corresponding to a plurality of pixels in the Y-axis direction.

Note that, in FIG. 5A, the light blocking portions that are indicated by dashed lines and extend in the lateral direction are the vertical light blocking portions of the second element isolating portions 20 that will be described later. The vertical light blocking portions of the second element isolating portions 20 are disposed closer to the side of the back surface 11B than the vertical light blocking portions 12V of the second light blocking unit 12. The two kinds of light blocking portions overlap each other in a plan view, but are actually disposed at different positions in the depth direction and are not in contact with each other.

As illustrated in FIG. 5B, the horizontal light blocking portion 12H extends in a lateral (horizontal) direction from the deepest location of the vertical light blocking portions 12V of the second light blocking unit 12. In FIG. 5B, the hatched region represents the horizontal light blocking portion 12H. As described later, the horizontal light blocking portion 12H has a function of reflecting light. The horizontal light blocking portion 12H has openings 12H1 formed at intervals. The etching stoppers 17 are provided in the openings 12H1. As will be described later, the horizontal light blocking portion 12H is formed by forming trenches in the depth direction and the horizontal direction through a wet etching process and filling the trenches with light blocking members. As the etching stoppers 17 are provided, progress of etching can be stopped, and, as a result, the openings 12H1 as illustrated in FIG. 5B are formed. In the present embodiment, it is assumed that the silicon substrate 11 having the plane index (111) is used, and the wet etching process is performed with an etching solution such as an alkaline aqueous solution capable of etching in the <110> direction and the <112> direction of the semiconductor substrate 11, for example. The etching stoppers 17 in FIG. 5B are a material exhibiting etching resistance to the alkaline aqueous solution, and can be formed with a crystal defect structure into which an impurity element such as boron (B) or hydrogen ions are implanted, an insulator such as an oxide, or the like, for example.

The horizontal light blocking portion 12H is located between the photoelectric conversion units 51 and the charge retaining units (MEM) 54 in the depth (Z-axis) direction, as illustrated in FIG. 4. The horizontal light blocking portion 12H is provided over the entire X-Y plane in the pixel array unit 111, except for the openings 12H1, as illustrated in FIG. 5B. The light that has entered from the back surface 11B and transmitted through the photoelectric conversion units 51 without being absorbed by the photoelectric conversion units 51 is reflected by the horizontal light blocking portion 12H of the second light blocking unit 12, and again enters the photoelectric conversion units 51, to contribute to photoelectric conversion. That is, the horizontal light blocking portion 12H of the second light blocking unit 12 functions as a reflector, and functions to reduce generation of noise due to light that has transmitted through the photoelectric conversion units 51 and entered the charge retaining units (MEM) 54, and increase the photoelectric conversion efficiency quantum efficiency (Qe) to increase sensitivity. Meanwhile, the vertical light blocking portions 12V of the second light blocking unit 12 function to prevent generation of noise such as color mixture due to light that has leaked from the adjacent sensor pixels 121 and entered the photoelectric conversion units 51.

As illustrated in FIG. 5B, the horizontal light blocking portion 12H includes a pair of first surfaces S1 extending in the horizontal direction, and a pair of second surfaces S2 and a pair of third surfaces S3 extending in a direction intersecting the pair of first surfaces. Each surface of the pair of first surfaces S1 is a surface parallel to a first crystal plane 11S1 of the semiconductor substrate 11, and the respective surfaces face each other in the Z-axis direction. Note that the first crystal plane 11S1 in the semiconductor substrate 11 is represented by the plane index (111). Meanwhile, each surface of a pair of second surfaces S2 is a surface parallel to a second crystal plane 11S2 of the semiconductor substrate 11. Although not illustrated in FIG. 5B, end surfaces S2 parallel to the second crystal plane 11S2 of the horizontal light blocking portion 12H are located on both end sides in the Y-axis direction in the pixel array unit 111. The second crystal plane 11S2 of the semiconductor substrate 11 is not in the effective pixel region but in a peripheral pixel region surrounding the effective pixel region. FIGS. 3 and 4 illustrate part of the effective pixel region, and the peripheral pixel region is provided outside the effective pixel region.

The second crystal plane 1182 in the semiconductor substrate 11 is represented by the plane index (111), and is inclined by about 19.5° with respect to the Z-axis direction. That is, the inclination angle of the second crystal plane 11S2 with respect to the horizontal plane (X-Y plane) is about 70.5°. The second crystal plane 11S2 is inclined with respect to the X-axis and the Y-axis in the horizontal plane (X-Y plane), and forms an angle of about 30° with respect to the Y-axis, for example. Further, the third surfaces S3 are the surfaces that define the outlines of the openings 12H1 having a rhombic planar shape, for example, and are the surface parallel to a third crystal plane 11S3 of the semiconductor substrate 11. The third crystal plane 11S3 of the semiconductor substrate 11 is inclined by about 19.5° with respect to the Z-axis direction, like the second crystal plane 11S2. That is, the inclination angle of the third crystal plane 11S3 with respect to the horizontal plane (X-Y plane) is about 70.5°. As described above, the Si residual region 22 other than the regions occupied by the horizontal light blocking portion 12H in the horizontal plane orthogonal to the thickness direction has a shape along the third crystal plane 11S3, for example, and has a rhombic shape in the example in FIGS. 5A and 5B.

As illustrated in FIGS. 4 and 5A, the vertical light blocking portions 12V of the second light blocking unit 12 are provided at intervals of a half pixel in the X-axis direction and extend in the Y-axis direction, and each charge retaining unit (MEM) 54 is disposed between two vertical light blocking portions 12V adjacent to each other in the X direction. Further, the horizontal light blocking portion 12H of the second light blocking unit 12 is disposed between the charge retaining units (MEM) 54 and the photoelectric conversion units 51, and the charge retaining units (MEM) 54 are surrounded by the vertical light blocking portions 12V and the horizontal light blocking portion 12H. Because of this, there is no possibility that light that has not been photoelectrically converted by the photoelectric conversion units 51 will enter the charge retaining units (MEM) 54, and thus, noise can be reduced. The second light blocking unit 12 is electrically connected to a wiring unit provided on the side of the front surface 11A of the semiconductor substrate 11.

As illustrated in FIG. 4, the second light blocking unit 12 has a two-layer structure that includes an inner layer portion 12A and an outer layer portion 12B surrounding the inner layer portion 12A. The inner layer portion 12A is formed with a material containing at least one of a single metal, a metal alloy, a metal nitride, and a metal silicide that have light blocking properties, for example. More specifically, the constituent material of the inner layer portion 12A may be Al (aluminum), Cu (copper), Co (cobalt), W (tungsten), Ti (titanium), Ta (tantalum), Ni (nickel), Mo (molybdenum), Cr (chromium), Ir (iridium), platinum iridium, TiN (titanium nitride), a tungsten silicon compound, or the like. Among these materials, Al (aluminum) is the most optically preferable constituent material. Note that the inner layer portion 12A may be formed with graphite or an organic material. The outer layer portion 12B is formed with an insulating material such as silicon oxide (SiOx), for example. The outer layer portion 12B ensures electrical insulation between the inner layer portion 12A and the semiconductor substrate 11.

### (Structure of the First Light Blocking Unit 13)

FIG. 6A is a cross-sectional view of the vertical light blocking portions of the first light blocking unit 13 and the second element isolating portions 20. FIG. 6A is a cross-sectional view taken along the line E-E defined in FIG. 4. FIG. 6B is a cross-sectional view of the horizontal light blocking portions 13H of the first light blocking unit 13. FIG. 6B is a cross-sectional view taken along the line F-F defined in FIG. 4. As illustrated in the drawings, the second element isolating portions 20 are arranged along the boundaries between the sensor pixels 121, and are disposed so as to surround the side surfaces of the photoelectric conversion units 51 of the respective sensor pixels 121. As illustrated in FIG. 6B, the first light blocking unit 13 is disposed in a staggered manner along the boundaries between the sensor pixels 121 in the X-Y plane. The horizontal light blocking portions 13H horizontally extending from the vertical light blocking portions 13V of the first light blocking unit 13 has a rhombic shape along the third crystal plane 11S3, for example.

The first light blocking unit 13 is formed by forming trenches along the boundaries between the sensor pixels 121 from the side of the back surface 11B of the semiconductor substrate 11, widening the trenches in the horizontal direction from the bottom of the trenches by a wet etching process, disposing an insulating layer in the outer layer portions of the trenches in the horizontal direction, and disposing a metal layer in the inner layer portions. When the trenches for the first light blocking unit 13 are widened in the horizontal direction by the wet etching process, etching is performed in a direction parallel to a specific crystal plane. The etching is stopped when the third crystal plane 11S3 of the plane index (111) finally appears. Therefore, if the etching is forcibly stopped before the third crystal plane 113 appears, the horizontal light blocking portions 13H of the first light blocking unit 13 can be formed in any desired shape.

As described above with reference to FIG. 4, the semiconductor device 1 includes reflective portions. The reflective portions are provided so as to extend substantially parallel to the back surface 11B in the semiconductor substrate 11, and reflect incident light L that has passed through the back surface 11B. Note that the path of the incident light L is not limited to the example illustrated in FIG. 4.

The reflective portions according to the first embodiment include the horizontal light blocking portions 12H and 13H. In the present specification, the horizontal light blocking portions 13H is sometimes referred to as the first reflective portions, and the horizontal light blocking portion 12H is sometimes referred to as the third reflective portion.

The horizontal light blocking portions 13H (first reflective portions) are disposed so as to overlap the transfer transistors TRZ (vertical gate electrodes 52V) when viewed from the Z direction. The horizontal light blocking portions 13H are provided so as to extend substantially parallel to the back surface 11B. Further, in the example illustrated in FIG. 4, the horizontal light blocking portions 13H are disposed in the photoelectric conversion units 51 (N⁻-type semiconductor region 51A).

The horizontal light blocking portion 12H (third reflective portion) is disposed between the photoelectric conversion units 51 and the charge retaining units (MEM) 54. The horizontal light blocking portion 12H is provided so as to extend substantially parallel to the back surface 11B.

### (Uneven Structure Unit 11C of the Back Surface 11B)

As illustrated in FIG. 4, the semiconductor substrate 11 has the back surface 11B. The semiconductor substrate 11 further includes an uneven structure unit 11C provided in the back surface 11B.

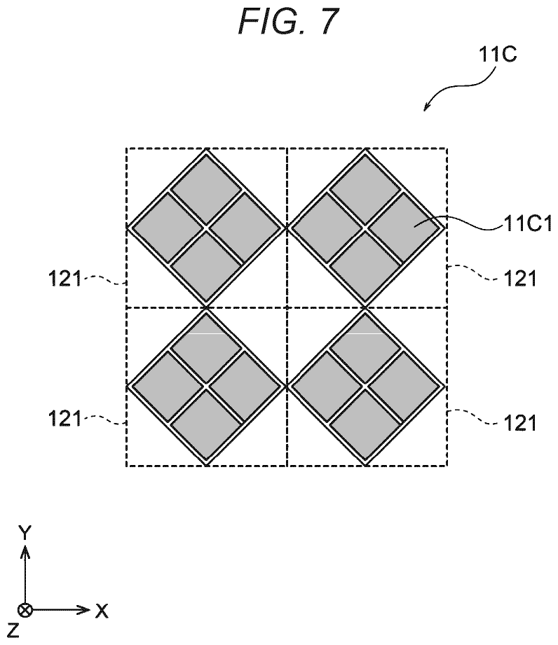

FIG. 7 is a plan view illustrating an example of the configuration of the uneven structure unit 11C according to the first embodiment. FIG. 7 illustrates the uneven structure unit 11C in four sensor pixels 121 as an example.

The uneven structure unit 11C includes a plurality of protrusions 11C1. One sensor pixel 121 includes four protrusions 11C1. Each of the protrusions 11C1 has a substantially polygonal outer shape in a plan view as viewed from the normal direction (Z direction) of the back surface 11B. In the example illustrated in FIG. 7, each of the protrusions 11C1 has a substantially quadrangular outer shape in a plan view as viewed from the Z direction.

Also, the plurality of protrusions 11C1 is disposed so as to be in contact with one another when viewed from the Z direction.

The uneven structure unit 11C can alleviate a rapid change in refractive index at an interface, which is one of the causes of light reflection, and reduce the influence of reflected light. That is, since the refractive index gradually changes in the incident direction of light, reflection of light can be reduced.

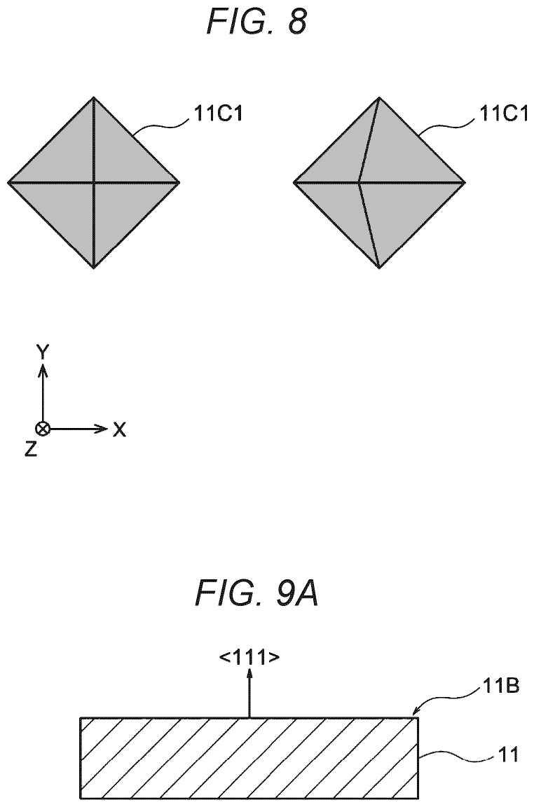

FIG. 8 is a plan view illustrating two examples of configurations of the protrusions 11C1 according to the first embodiment.

In the examples illustrated in FIG. 8, the protrusions 11C1 each have the shape of a substantially quadrangular pyramid (a pyramidal shape) in which the apex protrudes from the back surface 11B in the direction opposite from the front surface 11A. Note that, as illustrated on the left side in FIG. 8, in a case where the off angle of the substrate is zero, the apex of each substantially quadrangular pyramid faces a direction substantially perpendicular to the back surface 11B. The apex of the substantially quadrangular pyramid illustrated on the right side in FIG. 8 is inclined in accordance with the off angle.

As illustrated in FIG. 7, at least one side of the outer shape of each protrusion 11C1 viewed from the Z direction is inclined with respect to the array direction of the sensor pixels 121 (the boundaries between the sensor pixels 121). More specifically, the four sides of the outer shape of each protrusion 11C1 viewed from the Z direction are inclined by about 45° with respect to the array direction of the sensor pixels 121. The array direction of the sensor pixels 121 is the direction in which the element isolating portions 13V and 20 (see FIG. 6A) that isolate the plurality of sensor pixels 121 extend.

Further, the film 56 illustrated in FIG. 4 is provided along the uneven structure unit 11C. The film 56 includes a transparent insulating film or the like, for example.

The transparent insulating film is formed with silicon oxide (SiO₂), silicon nitride (SiN), silicon oxynitride (SiON), hafnium oxide (HfO₂), aluminum oxide (Al₂O₃), zirconium oxide (Zro₂), tantalum oxide (Ta₂O₅), titanium oxide (TiO₂), lanthanum oxide (La₂O₃), praseodymium oxide (Pr₂O₃), cerium oxide (CeO²), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), yttrium oxide (Y₂O₃), a resin, or the like, for example. Also, some of these materials may be combined and stacked, to form the transparent insulating film.

The planarizing film 55 is provided so as to planarize the uneven structure unit 11C and connect the back surface 11B to the color filters CF. The planarizing film 55 is only required to be formed with an organic material such as a resin, or an insulating film such as silicon oxide (SiO₂), for example.

### (Optical Path Length)

As illustrated in FIG. 4, the incident light L having passed through the back surface 11B is scattered by the uneven structure unit 11C. For example, the incident light L perpendicularly incident on the back surface 11B passes through the uneven structure unit 11C, and travels in the N⁻-type semiconductor region 51A while being tilted. In this manner, the traveling direction of the incident light L changes. As a result, the optical path length can be made longer. Also, in the example illustrated in FIG. 4, the incident light L having passed through the uneven structure unit 11C is reflected by the vertical light blocking portions 13V, and is further reflected by the horizontal light blocking portions 13H. As the number of reflective locations for the incident light L increases, the optical path length can be made even longer. That is, since the incident light L is reflected by the horizontal light blocking portions 13H, the optical path length of the incident light L1 in the N⁻-type semiconductor region 51A can be made longer. In this manner, the incident light L is confined in the N⁻-type semiconductor region 51A by the uneven structure unit 11C of the back surface 11B and the first light blocking unit 13, so that diffuse reflection can be easily caused, and the optical path length can be made longer. Thus, the incident light L is easily converted into charges in the N⁻-type semiconductor region 51A. As a result, the photoelectric conversion efficiency Qe can be increased.

### (Process of Manufacturing an Imaging Device)

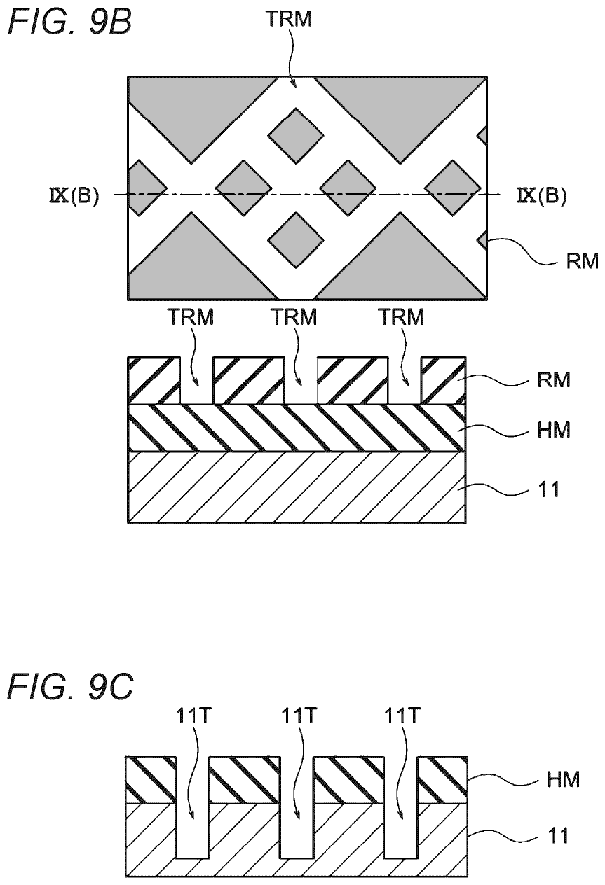

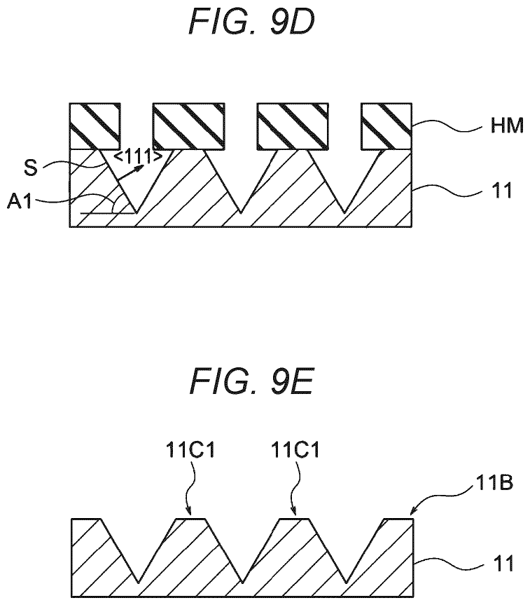

Next, a method for manufacturing the imaging device 101 according to the first embodiment is described with reference to process drawings in FIGS. 9A to 9E. Note that, in the description below, a method for manufacturing the uneven structure unit 11C will be mainly described, and the processes of forming the second light blocking unit 12, the first light blocking unit 13, the readout circuit 120, and the like will not be explained.

The second light blocking unit 12, the readout circuit 120, the first light blocking unit 13, and the uneven structure unit 11C are formed in this order, for example. However, either the formation of the uneven structure unit 11C or the formation of the first light blocking unit 13 may be performed first. In a case where the first light blocking unit 13 is formed after the formation of the uneven structure unit 11C, for example, the first light blocking unit 13 is only required to be formed while the uneven structure unit 11C is protected.

First, as illustrated in FIG. 9A, a silicon substrate 11 having a crystal orientation of the plane index (111) is prepared. The photoelectric conversion units 51 formed with the photodiodes PD are formed in the silicon substrate 11.

Next, as illustrated in FIG. 9B, a hard mask HM is formed on the silicon substrate 11, and a resist mask RM that selectively covers the hard mask HM is formed.

The upper part of FIG. 9B is a plan view illustrating the layout of the resist mask RM. The cross-sectional view in the lower part of FIG. 9B illustrates a cross-section taken along the line IX (B)-IX (B) defined in the plan view in the upper part of FIG. 9B. The resist mask RM is formed with a photoresist material containing a polymer as a principal component, for example. Trenches TRM are formed by patterning using photolithography, for example. The trenches TRM are formed so as to correspond to the respective sides of the protrusions 11C1 illustrated in FIG. 7.

That is, in the process illustrated in FIG. 9B, the hard mask HM (first mask material) is formed on the back surface 11B, the resist mask RM (second mask material) is formed on the hard mask HM, and a pattern having at least one trench TRM inclined with respect to the array direction of the pixels as viewed from the Z direction is formed in the resist mask RM.

Next, as illustrated in FIG. 9C, the hard mask HM and the silicon substrate 11 are processed by dry etching. That is, the hard mask HM and the silicon substrate 11 are processed, with the resist mask RM being used as the mask. As a result, trenches 11T are formed in the silicon substrate 11. In a case where the back surface 11B is exposed without the trenches 11T being formed, the crystal anisotropic wet etching in the subsequent process hardly proceeds. This is because a surface included in the plane index (111) has wet etching resistance.

Next, as illustrated in FIG. 9D, a predetermined alkaline aqueous solution is injected into the trenches 11T, and wet etching is performed, to partially remove the silicon substrate 11. That is, the silicon substrate 11 is processed, with the hard mask HM being used as the mask. As the alkaline aqueous solution, KOH, NaOH, CsOH, or the like can be used in the case of an inorganic solution, and EDP (ethylenediamine pyrocatechol aqueous solution), N₂H₄ (hydrazine), NH₄OH (ammonium hydroxide), TMAH (tetramethylammonium hydroxide), or the like can be used in the case of an organic solution.

Here, etching proceeds until surfaces S having wet etching resistance are exposed. The surfaces S are surfaces along the crystal planes of the semiconductor substrate 11. The surfaces S are represented by the plane index (111). The six surfaces included in the plane index (111) have resistance to crystal anisotropic wet etching. Further, the inclination angle of the surfaces S with respect to the horizontal plane (X-Y plane) is an angle A1.

Specifically, in the Si (111) substrate, the etching rate in the <110> direction, which is a direction in which there is one or two Si back bonds, is sufficiently higher than the etching rate in the <111> direction, which is a direction in which there are three Si back bonds. Therefore, in the present embodiment, etching in the X-axis direction progresses, while etching hardly progresses in the Y-axis direction and the Z-axis direction.

Next, as illustrated in FIG. 9E, the hard mask HM is removed. Thus, the uneven structure unit 11C including the plurality of protrusions 11C1 provided in the back surface 11B is completed (see FIG. 7).

### (Materials of the Second Light Blocking Unit 12, the First Light Blocking Unit 13, and the Second Element Isolating Portions 20)

The second light blocking unit 12, the first light blocking unit 13, and the second element isolating portions 20 in the present embodiment characteristically absorb or reflect incident light, and various materials can be adopted. For example, as an example of the material, an insulating film of SiN, SiO₂, or the like may be used. Alternatively, a metal material such as tungsten or aluminum may be used. Tungsten characteristically absorbs light, while aluminum characteristically reflects light. Other than this, the above material may be polysilicon. Polysilicon excels in light reflection characteristics. Alternatively, the above material may be a metal oxide film (aluminum oxide, aluminum nitride, or the like, for example). Alternatively, the above material may be a material containing carbon (C), such as a carbon compound or an organic material. Alternatively, the above material may be an electrochromic material. An electrochromic material is a material (polyaniline, porogen, or the like, for example) capable of switching light reflectance or absorptivity when a voltage or a current is applied thereto.

The second light blocking unit 12, the first light blocking unit 13, and the second element isolating portions 20 only need to have light absorption characteristics or reflection characteristics. Note that, in the present specification, the case of light absorption and the case of light reflection are collectively referred to as “light blocking”. That is, “light blocking” in the present specification means having characteristics of not allowing light transmission. Note that a case where light is slightly transmitted is also interpreted as being included in the “light blocking”.

From the viewpoint of the optical path length, it is more preferable that all the materials of the second light blocking unit 12, the first light blocking unit 13, and the second element isolating portions 20 have high-reflection characteristics. Accordingly, the optical path length of the incident light L in the N⁻-type semiconductor region 51A can be made longer. As a result, the photoelectric conversion efficiency Qe can be increased.

As described above, in the first embodiment, the uneven structure unit 11C of the back surface 11B scatters (diffracts) light passing through the back surface 11B. The horizontal light blocking portions 12H and 13H reflect the incident light L having passed through the back surface 11B. As the incident light L is diffracted and reflected, the optical path length can be made longer. As a result, the photoelectric conversion efficiency Qe, which is the sensitivity, can be increased. The first light blocking unit 13 is relatively easily manufactured, because the vertical light blocking portions 13V and the horizontal light blocking portions 13H are integrally formed. Furthermore, the cross-sectional shape of the first light blocking unit 13 is a T-shape, and the horizontal light blocking portions 13H do not penetrate through the vertical light blocking portions 13V. Accordingly, there is no possibility that the vertical light blocking portions 13V will interfere with movement of electrons generated in the photoelectric conversion units 51.

Further, the height of the vertical light blocking portions 13V of the first light blocking unit 13 can be adjusted as desired, and the height of the second element isolating portions 20 can also be adjusted as desired. Accordingly, it is possible to increase the photoelectric conversion efficiency Qe, which is the sensitivity, without an increase in noise or color mixture, by optimizing the heights of the vertical light blocking portions 13V and the second element isolating portions 20 so as not to hinder movement of electrons generated in the photoelectric conversion units 51.

Moreover, the vertical light blocking portions 13V of the first light blocking unit 13 are disposed at the boundary portions between the pixels, and it is possible to prevent light leakage into the adjacent pixels, and reduce blooming due to color mixture. Further, as the second element isolating portions 20, in addition to the first light blocking unit 13, are provided at the boundary portions between the pixels, the effect of reducing inter-pixel crosstalk can be further enhanced.

Furthermore, as the second light blocking unit 12 covering the charge retaining units (MEM) 54 is provided in addition to the first light blocking unit 13, the possibility of light entering the charge retaining units (MEM) 54 can be eliminated, and noise can be reduced.

Note that, in the first embodiment, the protrusions 11C1 may be recesses. That is, the uneven structure unit 11C may include a plurality of protrusions. In this case, a plurality of recesses is formed so that the apex of each substantially quadrangular pyramid protrudes from the back surface 11B toward the front surface 11A.

### (Crystal Orientation of Surfaces of the Uneven Structure Unit 11C)

Further, the semiconductor substrate 11 is a silicon substrate, as described above. The uneven structure unit 11C includes inclined surfaces (surfaces S) that are inclined with respect to the back surface 11B. The inclined surfaces (surfaces S) are crystal planes of silicon of the plane index (111), which are (111) planes of silicon or surfaces equivalent to the (111) planes. Accordingly, the four surfaces S, which are the four side surfaces of a substantially quadrangular pyramid illustrated in FIG. 8, include crystal planes of silicon of the plane index (111), which are (111) planes or surfaces equivalent to the (111) planes. This is because, in wet etching, the etching rate of the plane index (111) is lower than the etching rates of the plane index (110) and the plane index (112).

### (Angle of Protrusions/Recesses)

Meanwhile, the inclination angle of the surfaces S (inclined surfaces) with respect to the horizontal plane (X-Y plane, or the back surface 11B) is the angle A1 (see FIG. 9D). In a case where the angle A1 is greater than about 45°, which is a case where the angle of the apex of each protrusion 11C1 is an acute angle, the photoelectric conversion efficiency Qe becomes higher. Therefore, the inclination angle of the surfaces S (inclined surfaces) with respect to the horizontal plane (X-Y plane, or the back surface 11B) is more preferably about 90° or smaller, for example.

### COMPARATIVE EXAMPLES

Next, comparative examples are described.

In a case where the material of the first light blocking unit 13 and the element isolating portions 20 is aluminum, and the uneven structure unit 11C is provided, the photoelectric conversion efficiency Qe can be increased by about 30% to 50% in simulations, for example, compared with the photoelectric conversion efficiency Qe in a case where the material of the first light blocking unit 13 and the element isolating portions 20 is tungsten, and the uneven structure unit 11C is not provided.

Further, as another method for forming the uneven structure unit 11C, it is also conceivable to form recesses having surfaces inclined stepwise by repeating dry etching using a mask a plurality of times, for example. In this case, however, there is a possibility that the incident light L is easily scattered on the inclined surfaces of the stepwise shape.

In the first embodiment, on the other hand, the protrusions 11C1 having smoothly inclined surfaces (surface S) in accordance with the plane index of the substrate are exposed by wet etching (see FIG. 9D). As the surfaces S are smoothly inclined surfaces, scattering of the incident light L on the surfaces S can be reduced. Thus, a larger amount of the incident light L easily enters the semiconductor substrate 11, and is easily reflected by the second light blocking unit 12, the first light blocking unit 13, and the element isolating portions 20 in the pixels. As a result, the photoelectric conversion efficiency Qe can be further increased.

### (Modification of the First Embodiment)

FIG. 10 is a plan view illustrating an example of the configuration of the uneven structure unit 11C according to a first modification of the first embodiment. The modification of the first embodiment differs from the first embodiment in that the semiconductor substrate 11 is a single-crystal silicon substrate 11 having a crystal orientation of a plane index (100).

Each protrusion 11C1 has a substantially quadrangular outer shape in a plan view viewed from the Z direction, as in the first embodiment. In the example illustrated in FIG. 10, the protrusions 11C1 are arranged in the array direction of the sensor pixels 121. The four sides of the outer shape of each protrusion 11C1 viewed from the Z direction are substantially parallel to the boundaries between the sensor pixels 121. That is, the four sides of the outer shape of each protrusion 11C1 viewed from the Z direction are substantially parallel to the element isolating portions 13V and 20 illustrated in FIG. 6A.

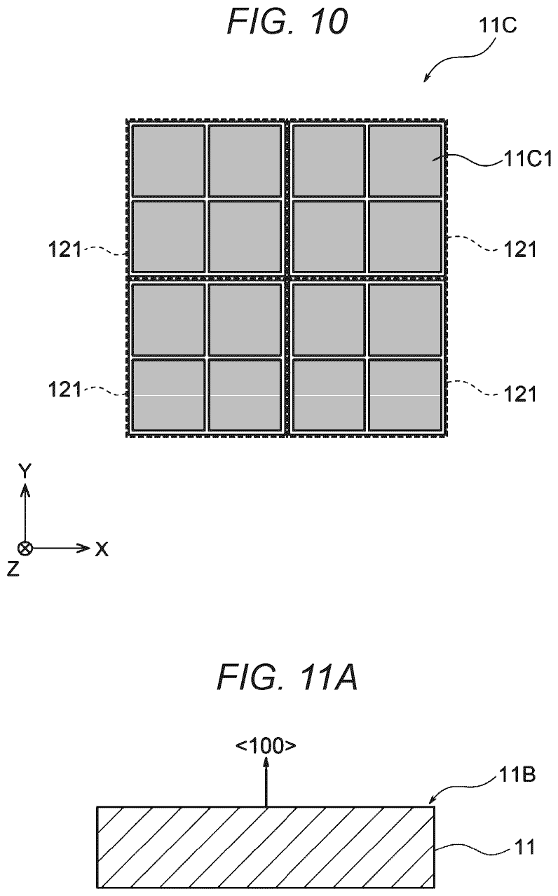

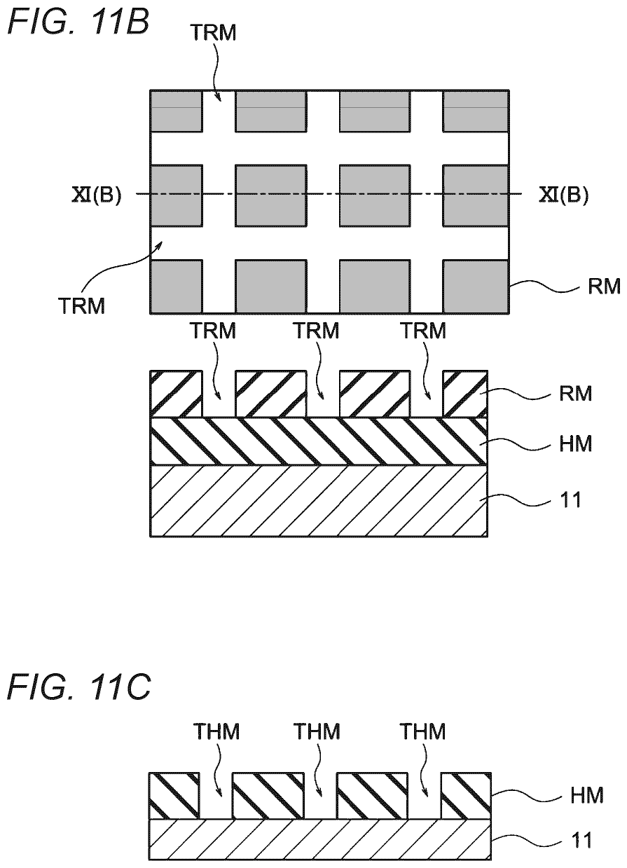

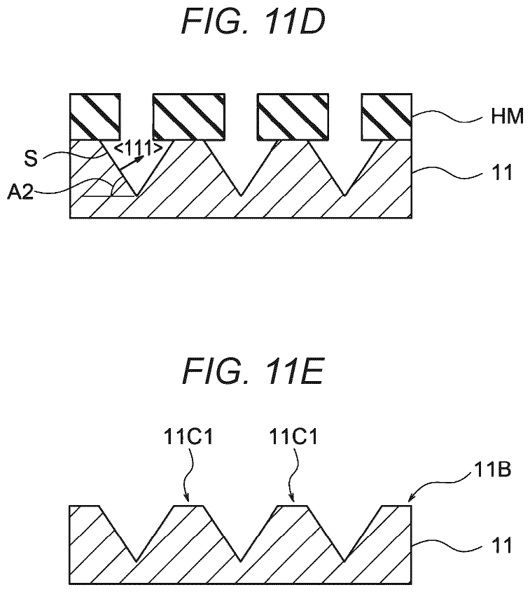

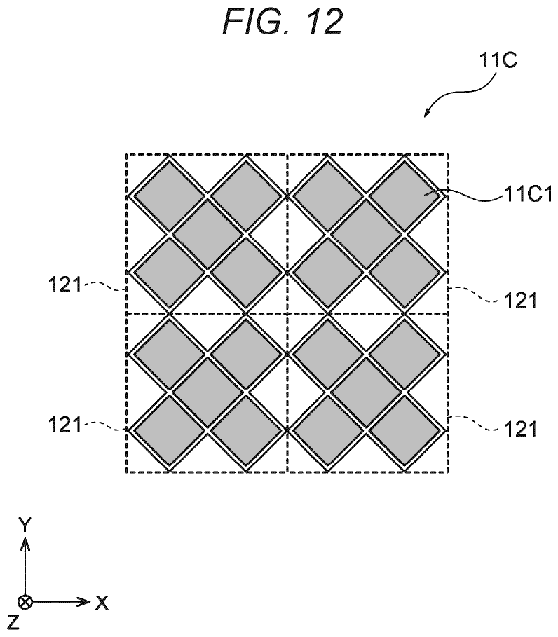

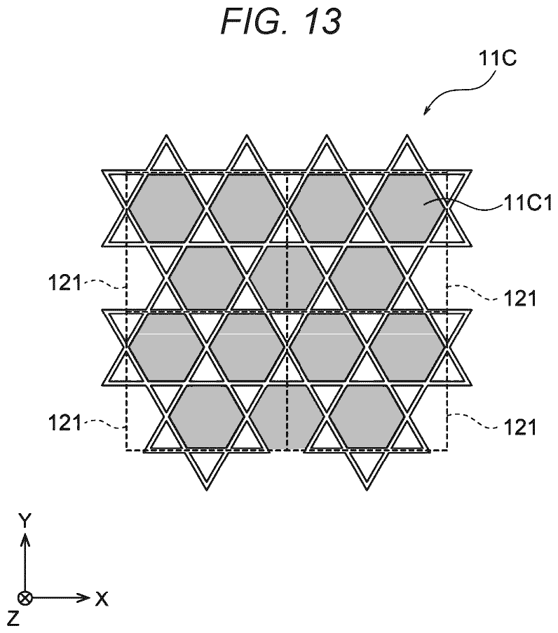

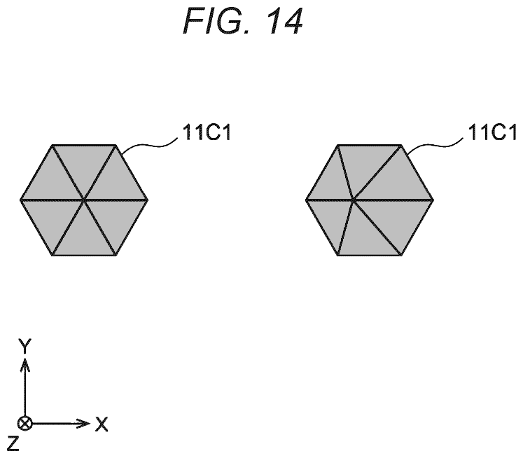

Next, a method for manufacturing the imaging device 101 according to the modification of the first embodiment is described with reference to process drawings in FIGS. 11A to 11E.

First, as illustrated in FIG. 11A, a silicon substrate 11 having a crystal orientation of the plane index (100) is prepared.

Next, as illustrated in FIG. 11B, a hard mask HM is formed on the silicon substrate 11, and a resist mask RM that selectively covers the hard mask HM is formed.

The upper part of FIG. 11B is a plan view illustrating the layout of the resist mask RM. The cross-sectional view in the lower part of FIG. 11B illustrates a cross-section taken along the line XI (B)-XI (B) defined in the plan view in the upper part of FIG. 11B. The resist mask RM is formed with a photoresist material containing a polymer as a principal component, for example. Trenches TRM are formed by patterning using photolithography, for example. The trenches TRM are formed so as to correspond to the respective sides of the protrusions 11C1 illustrated in FIG. 10.

Next, as illustrated in FIG. 11C, the hard mask HM is processed by dry etching. Thus, trenches THM that reach the back surface 11B are formed.

Next, as illustrated in FIG. 11D, a predetermined alkaline aqueous solution is injected into the trenches THM, and wet etching is performed, to partially remove the silicon substrate 11.

Here, etching proceeds until surfaces S having wet etching resistance are exposed. The surfaces S are surfaces along the crystal planes of the semiconductor substrate 11. The surfaces S are represented by the plane index (111). The six surfaces included in the plane index (111) have resistance to crystal anisotropic wet etching. Further, the inclination angle of the surfaces S with respect to the horizontal plane (X-Y plane) is an angle A2.

The angle A2 may be an angle different from the angle A1 illustrated in FIG. 9D described in the first embodiment, because of the difference in the crystal orientation of the semiconductor substrate 11. The angle A2 is more preferably about 90° or smaller, for example, like the angle A1.

Next, as illustrated in FIG. 11E, the hard mask HM is removed. Thus, the uneven structure unit 11C including the plurality of protrusions 11C1 provided in the back surface 11B is completed (see FIG. 10).

As in the modification of the first embodiment, the plane index of the semiconductor substrate 11 may be changed. In this case, effects similar to those of the first embodiment can also be achieved.

Furthermore, by changing the shape and the layout of the trenches TRM formed in the resist mask RM, the plane orientation of the semiconductor substrate 11, and the like, it is possible to change the shape, the layout, and the like of the protrusions 11C1.

### Second Embodiment

FIG. 12 is a plan view illustrating an example of the configuration of an uneven structure unit 11C according to a second embodiment. The second embodiment differs from the first embodiment in the layout of protrusions 11C1.

In the example illustrated in FIG. 12, five protrusions 11C1 are provided in one sensor pixel 121. The pattern of the trenches TRM to be formed in the resist mask RM is changed, so that the uneven structure unit 11C illustrated in FIG. 12 is obtained.

The layout of the protrusions 11C1 may be changed as in the second embodiment. In this case, effects similar to those of the first embodiment can also be achieved.

### Third Embodiment

FIG. 13 is a plan view illustrating an example of the configuration of an uneven structure unit 11C according to a third embodiment. The third embodiment differs from the first embodiment in the shape and the layout of protrusions 11C1.

In the example illustrated in FIG. 13, three protrusions 11C1 are provided in one sensor pixel 121.

FIG. 14 is a plan view illustrating two examples of configurations of the protrusions 11C1 according to the third embodiment.

In the examples illustrated in FIG. 14, the protrusions 11C1 each have the shape of a substantially hexagonal pyramid in which the apex protrudes from the back surface 11B in the direction opposite from the front surface 11A. Note that, as illustrated on the left side in FIG. 14, in a case where the off angle of the substrate is zero, the apex of each substantially hexagonal pyramid faces a direction substantially perpendicular to the back surface 11B. The apex of the substantially hexagonal pyramid illustrated on the right side in FIG. 14 is inclined in accordance with the off angle.

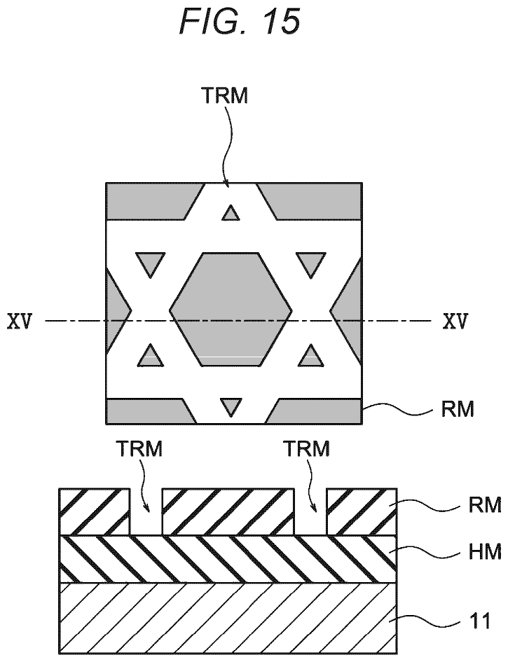

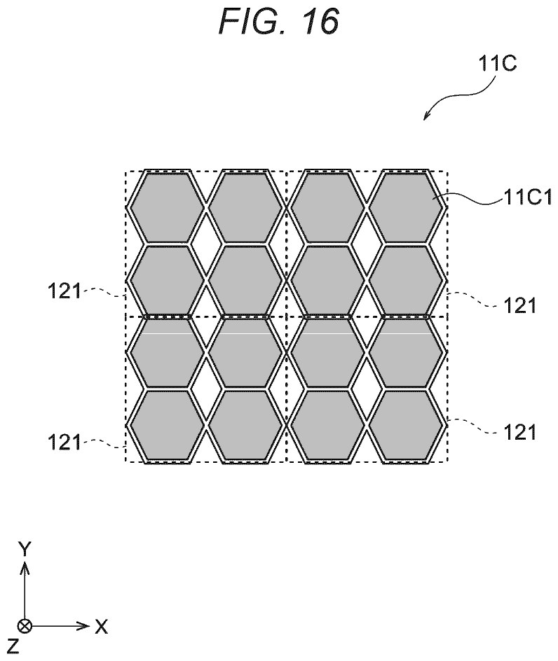

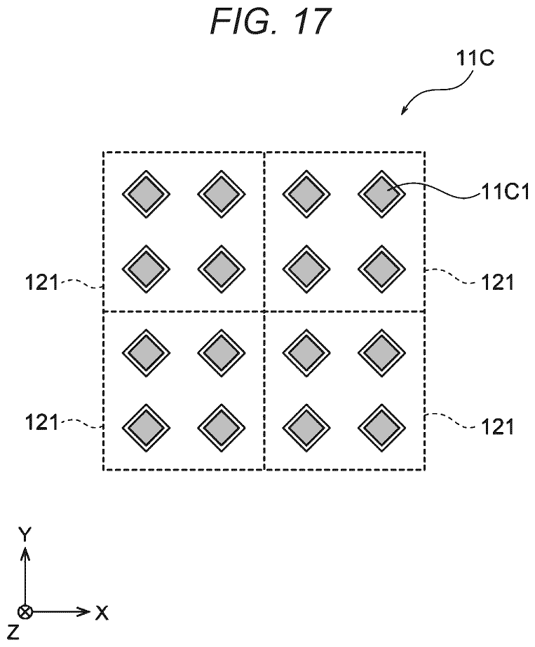

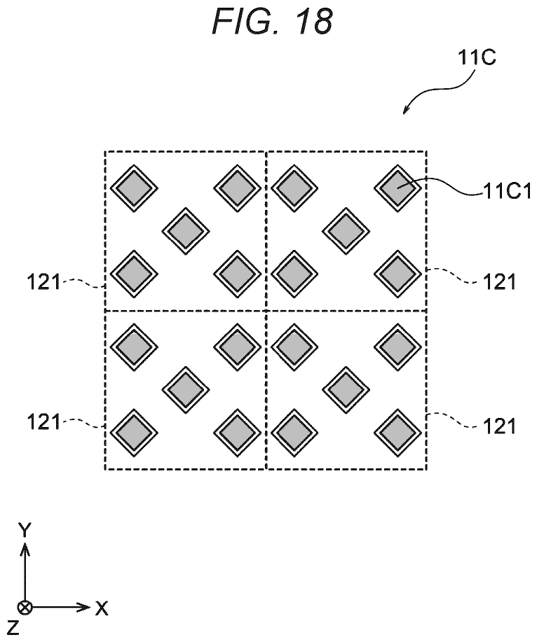

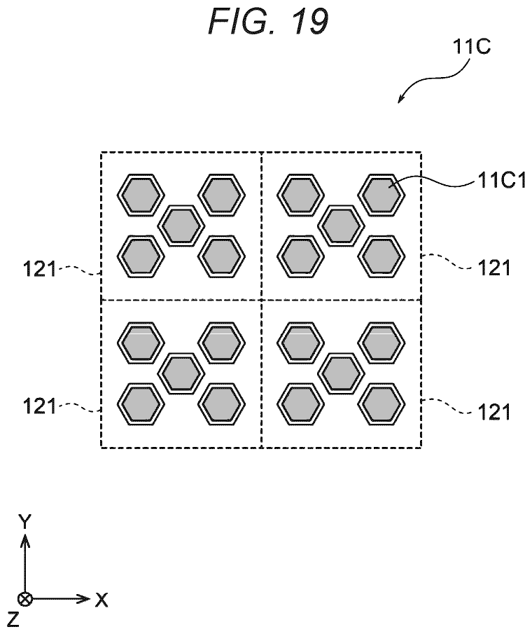

Next, a method for manufacturing an imaging device 101 according to the third embodiment is described with reference to a process drawing in FIG. 15.

After a silicon substrate 11 of the plane index (111) is prepared (see FIG. 9A), a hard mask HM is formed on the silicon substrate 11, and a resist mask RM selectively covering the hard mask HM is formed, as illustrated in FIG. 15.

The upper part of FIG. 15 is a plan view illustrating the layout of the resist mask RM. The cross-sectional view in the lower part of FIG. 15 illustrates a cross-section taken along the line XV-XV defined in the plan view in the upper part of FIG. 15. The resist mask RM is formed with a photoresist material containing a polymer as a principal component, for example. Trenches TRM are formed by patterning using photolithography, for example. The trenches TRM are formed so as to correspond to the respective sides of the protrusions 11C1 illustrated in FIG. 13.

After that, steps similar to the steps shown in FIGS. 9C to 9E are carried out. Accordingly, the pattern of the trenches TRM to be formed in the resist mask RM is changed, so that the uneven structure unit 11C illustrated in FIG. 13 is obtained.

The shape and the layout of the protrusions 11C1 may be changed as in the third embodiment. In this case, effects similar to those of the first embodiment can also be achieved.

Further, the six surfaces S, which are the six side surfaces of a substantially hexagonal pyramid illustrated in FIG. 14, include crystal planes of silicon of the plane index (111), which are (111) planes or surfaces equivalent to the (111) planes.

Furthermore, as described above, in the wet etching, an etching solution that has a high etching resistance in the <111> direction of the semiconductor substrate 11 and allows etching in the <110> direction and the <112> direction of the semiconductor substrate 11 is used, for example. The <110> direction has six-time rotational symmetry, as viewed from a (111) plane. The <110> direction includes a [110] direction and a direction equivalent to the [110] direction. Also, the <112> direction has six-time rotational symmetry as viewed from a (111) plane. The <112> direction includes a [112] direction and a direction equivalent to the direction. Thus, the side surfaces of each substantially hexagonal pyramid are easily formed at the time of wet etching, and the protrusions 11C1 each having the shape of a substantially hexagonal pyramid can be more easily formed.

### Fourth Embodiment

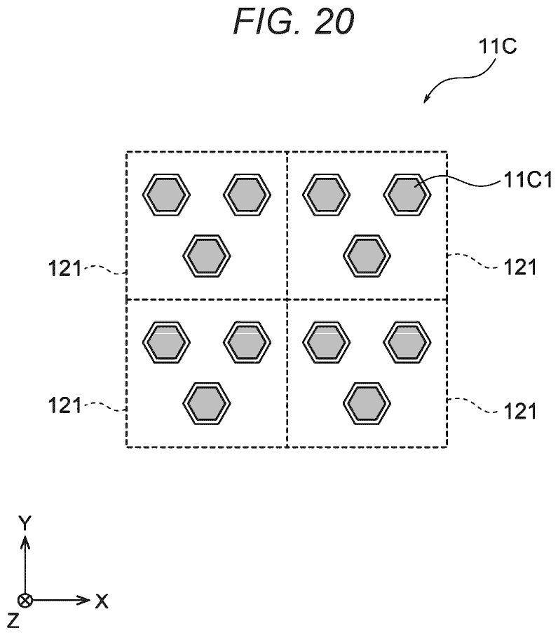

FIG. 16 is a plan view illustrating an example of the configuration of an uneven structure unit 11C according to a fourth embodiment. The fourth embodiment differs from the third embodiment in the layout of protrusions 11C1.

In the example illustrated in FIG. 16, four protrusions 11C1 are provided in one sensor pixel 121. The pattern of the trenches TRM to be formed in the resist mask RM is changed, so that the uneven structure unit 11C illustrated in FIG. 16 is obtained.

The layout of the protrusions 11C1 may be changed as in the fourth embodiment. In this case, effects similar to those of the third embodiment can also be achieved.

### Fifth Embodiment

FIGS. 17 to 20 are plan views each illustrating an example of the configuration of an uneven structure unit 11C according to a fifth embodiment. The fifth embodiment differs from the first embodiment in that intervals are maintained between protrusions 11C1.

A plurality of the protrusions 11C1 may be disposed at intervals, as viewed from the Z direction.

In the example illustrated in FIG. 17, intervals are maintained between the protrusions 11C1 of the first embodiment illustrated in FIG. 7. Four protrusions 11C1 are provided in one sensor pixel 121. The protrusions 11C1 each have the shape of a substantially quadrangular pyramid. The pattern of the trenches TRM to be formed in the resist mask RM is changed, so that the uneven structure unit 11C illustrated in FIG. 17 is obtained.

In the example illustrated in FIG. 18, intervals are maintained between the protrusions 11C1 of the second embodiment illustrated in FIG. 12. Five protrusions 11C1 are provided in one sensor pixel 121. The protrusions 11C1 each have the shape of a substantially quadrangular pyramid. The pattern of the trenches TRM to be formed in the resist mask RM is changed, so that the uneven structure unit 11C illustrated in FIG. 18 is obtained.

In the example illustrated in FIG. 19, five protrusions 11C1 are provided in one sensor pixel 121. The protrusions 11C1 each have the shape of a substantially hexagonal pyramid. The pattern of the trenches TRM to be formed in the resist mask RM is changed, so that the uneven structure unit 11C illustrated in FIG. 19 is obtained.

In the example illustrated in FIG. 20, intervals are maintained between the protrusions 11C1 of the third embodiment illustrated in FIG. 13. Three protrusions 11C1 are provided in one sensor pixel 121. The protrusions 11C1 each have the shape of a substantially hexagonal pyramid. The pattern of the trenches TRM to be formed in the resist mask RM is changed, so that the uneven structure unit 11C illustrated in FIG. 20 is obtained.

Intervals may be maintained between the protrusions 11C1, as in the fifth embodiment. In this case, effects similar to those of the first embodiment can also be achieved.

### Sixth Embodiment

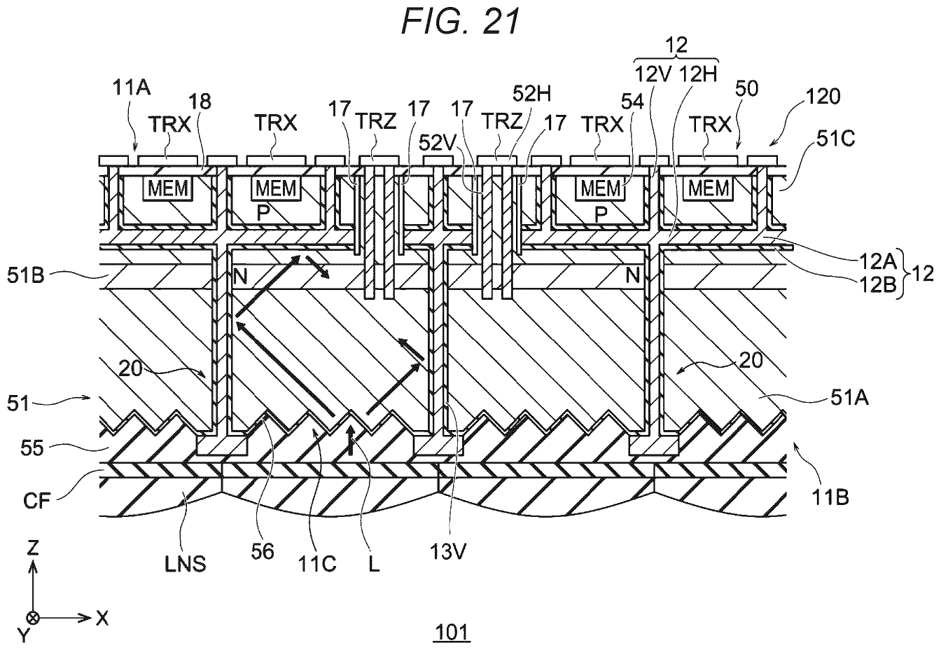

FIG. 21 is a cross-sectional view illustrating an example of the configuration of an imaging device 101 according to a sixth embodiment. The sixth embodiment differs from the first embodiment in that the horizontal light blocking portions 13H are not provided, the vertical light blocking portions 12V and 13V are provided and penetrate the semiconductor substrate 11, and the vertical light blocking portions 12V and the element isolating portions 20 are provided and penetrate the semiconductor substrate 11.

In a case where the horizontal light blocking portions 13H are not provided, the horizontal light blocking portion 12H reflects the incident light L, so that the optical path length can be made longer. As a result, the photoelectric conversion efficiency Qe can be increased.

Furthermore, the element isolating portions 13V and 20 have light blocking properties thanks to the inner layer portions, and can prevent entry of incident light into another adjacent pixel, and reduce crosstalk. Also, the element isolating portions 13V and 20 reaching the second light blocking unit 12 can reduce blooming.

The configurations of the first light blocking unit 13 and the element isolating portions 20 may be changed as in the sixth embodiment. In this case, effects similar to those of the first embodiment can also be achieved.

### Seventh Embodiment

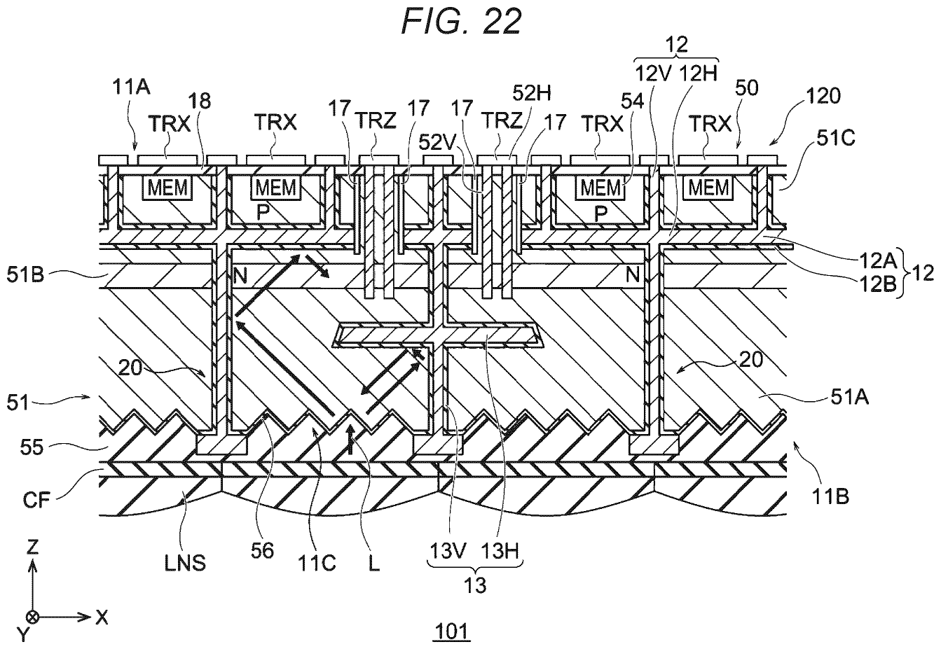

FIG. 22 is a cross-sectional view illustrating an example of the configuration of an imaging device 101 according to a seventh embodiment. The seventh embodiment differs from the sixth embodiment (see FIG. 21) in that horizontal light blocking portions 13H are provided. The other components of the seventh embodiment may be similar to the corresponding components of the sixth embodiment.

The configuration of the first light blocking unit 13 may be changed as in the seventh embodiment. In this case, effects similar to those of the sixth embodiment can also be achieved.

### Eighth Embodiment

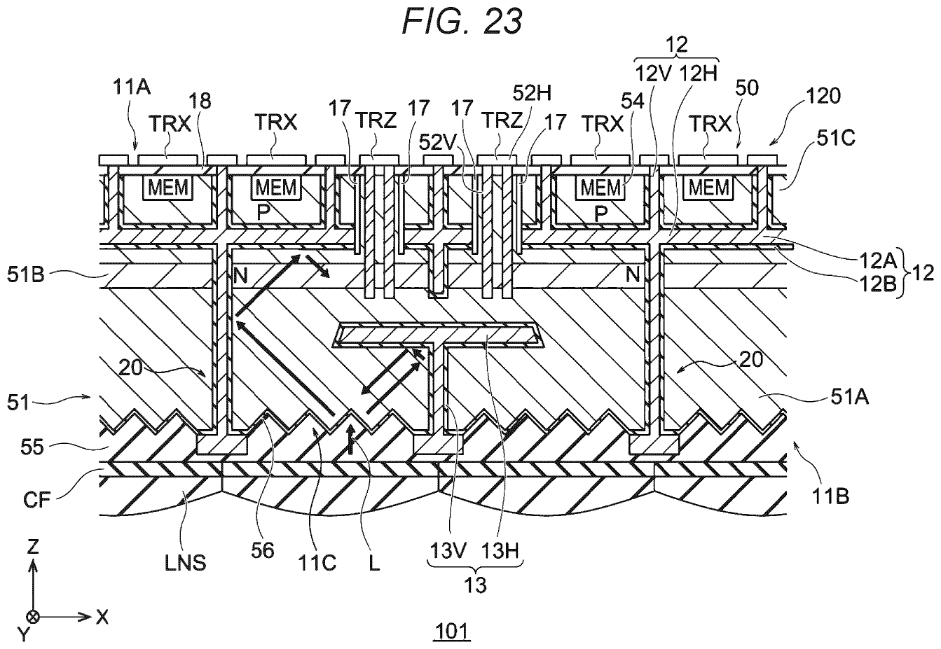

FIG. 23 is a cross-sectional view illustrating an example of the configuration of an imaging device 101 according to an eighth embodiment. The eighth embodiment differs from the first embodiment in that the vertical light blocking portions 12V and the element isolating portions 20 are provided and penetrate the semiconductor substrate 11, and the vertical light blocking portions 12V immediately above the vertical light blocking portions 13V protrude from the horizontal light blocking portion 12H toward the vertical light blocking portions 13V. The other components of the eighth embodiment may be similar to the corresponding components of the first embodiment. Note that a distance is provided between the lower ends of the protruding vertical light blocking portions 12V and the first light blocking unit 13.

The element isolating portions 20 and the vertical light blocking portions 12V have light blocking properties thanks to the inner layer portions, and can prevent entry of incident light into another adjacent pixel, and reduce crosstalk.

The configurations of the element isolating portions 20 and the second light blocking unit 12 may be changed as in the eighth embodiment. In this case, effects similar to those of the first embodiment can also be achieved.

### Ninth Embodiment

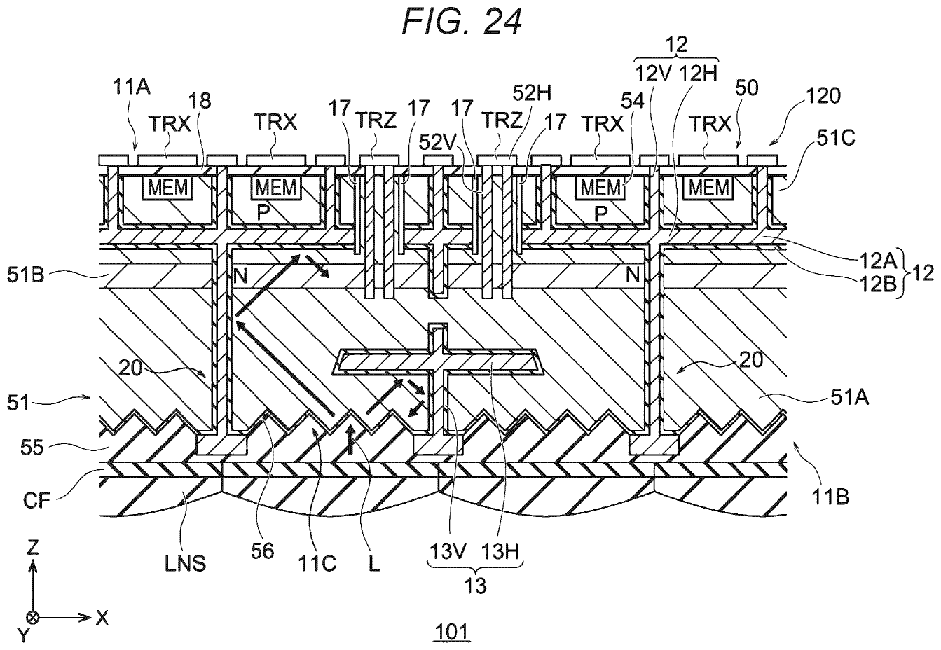

FIG. 24 is a cross-sectional view illustrating an example of the configuration of an imaging device 101 according to a ninth embodiment. The ninth embodiment differs from the eighth embodiment (see FIG. 23) in that the vertical light blocking portions 13V on the side of the back surface 11B penetrate through the horizontal light blocking portions 13H from the back surface 11B to the side of the front surface 11A. The first light blocking unit 13 has a substantially cross shape. The other components of the ninth embodiment may be similar to the corresponding components of the eighth embodiment.

The element isolating portions 13V and 20 have light blocking properties thanks to the inner layer portions, and can prevent entry of incident light into another adjacent pixel, and reduce crosstalk.

The configuration of the first light blocking unit 13 may be changed as in the ninth embodiment. In this case, effects similar to those of the eighth embodiment can also be achieved.

### Tenth Embodiment

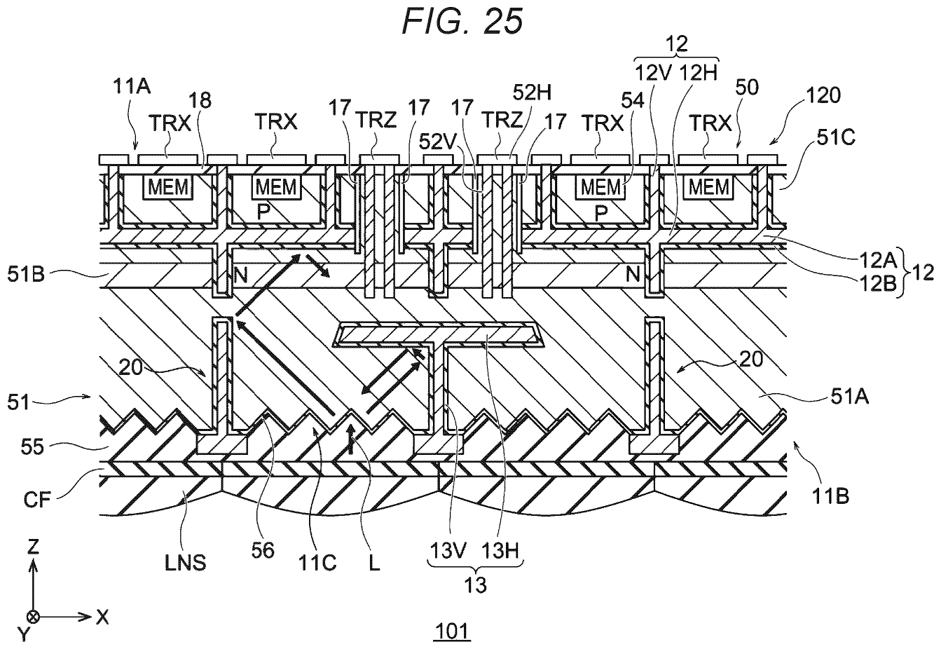

FIG. 25 is a cross-sectional view illustrating an example of the configuration of an imaging device 101 according to a tenth embodiment. This embodiment differs from the first embodiment in that the vertical light blocking portions 12V immediately above the first light blocking unit 13 protrude from the horizontal light blocking portion 12H toward the first light blocking unit 13, and the vertical light blocking portions 12V immediately above the element isolating portions 20 protrude from the horizontal light blocking portion 12H toward the element isolating portions 20. The other components of the tenth embodiment may be similar to the corresponding components of the first embodiment.

The vertical light blocking portions 12V have light blocking properties thanks to the inner layer portion, and can prevent entry of incident light into another adjacent pixel, and reduce crosstalk.

The configuration of the second light blocking unit 12 may be changed as in the tenth embodiment. In this case, effects similar to those of the first embodiment can also be achieved.

### Eleventh Embodiment

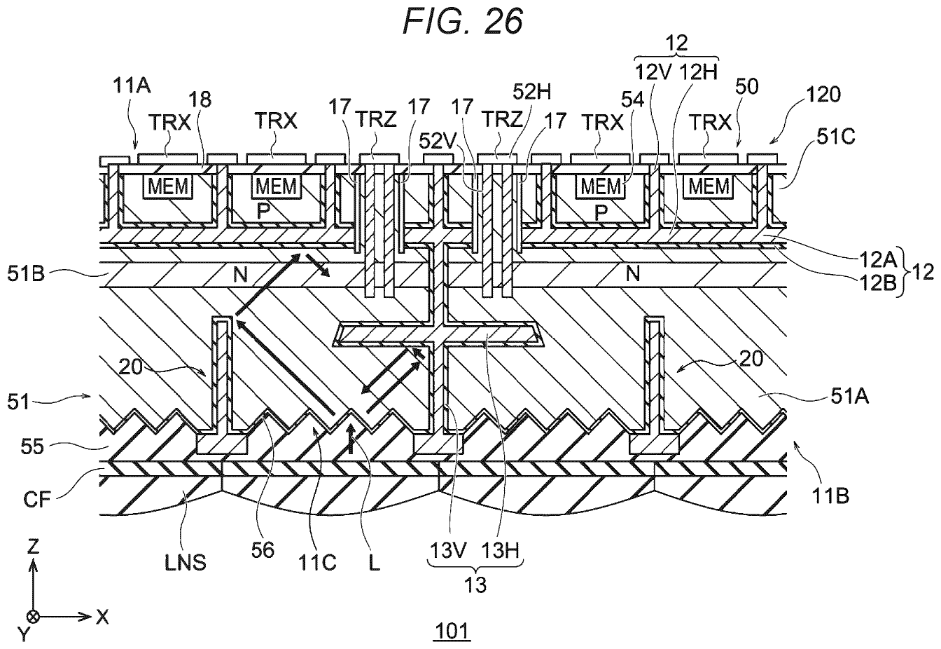

FIG. 26 is a cross-sectional view illustrating an example of the configuration of an imaging device 101 according to an eleventh embodiment. The eleventh embodiment differs from the first embodiment in that the vertical light blocking portions 12V and 13V are provided and penetrate the semiconductor substrate 11. The other components of the eleventh embodiment may be similar to the corresponding components of the first embodiment.

The vertical light blocking portions 12V and 13V have light blocking properties thanks to the inner layer portions, and can prevent entry of incident light into another adjacent pixel, and reduce crosstalk.

The configuration of the vertical light blocking portions 13V may be changed as in the eleventh embodiment. In this case, effects similar to those of the first embodiment can also be achieved.

### Twelfth Embodiment

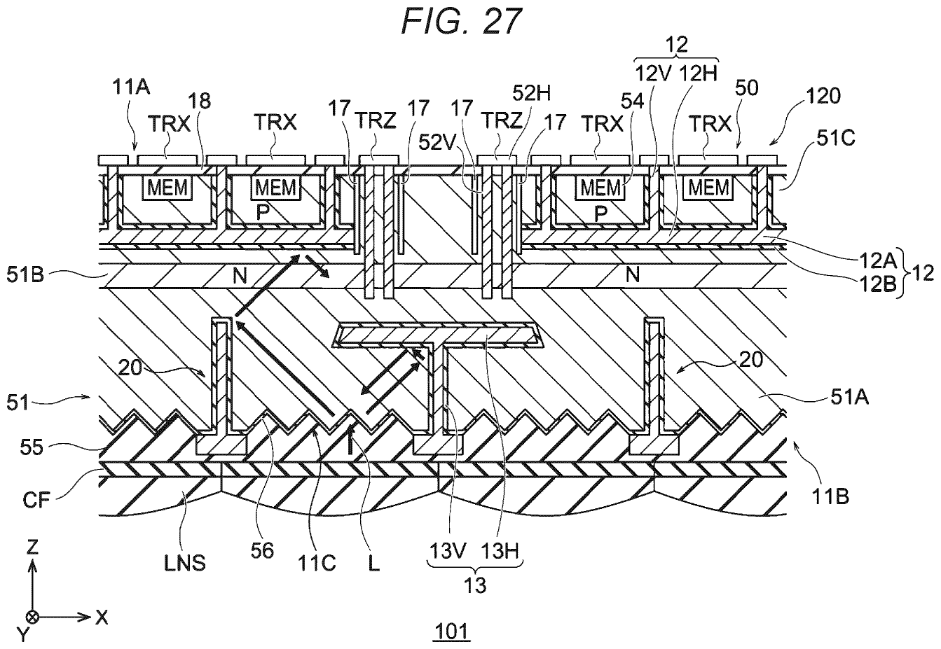

FIG. 27 is a cross-sectional view illustrating an example of the configuration of an imaging device 101 according to a twelfth embodiment. The twelfth embodiment differs from the first embodiment in that the second light blocking unit 12 immediately above the first light blocking unit 13 is not provided. The other components of the twelfth embodiment may be similar to the corresponding components of the first embodiment.

The configuration of the second light blocking unit 12 may be changed as in the twelfth embodiment. In this case, effects similar to those of the first embodiment can also be achieved.

### Thirteenth Embodiment

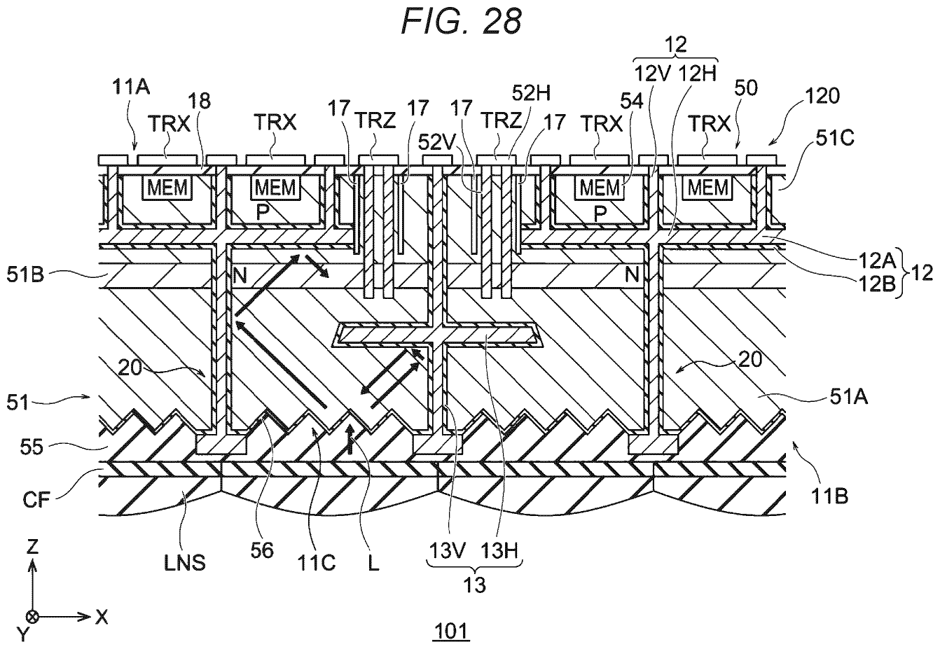

FIG. 28 is a cross-sectional view illustrating an example of the configuration of an imaging device 101 according to a thirteenth embodiment. The thirteenth embodiment differs from the seventh embodiment (see FIG. 22) in that the horizontal light blocking portion 12H immediately above the first light blocking unit 13 is not provided. The other components of the thirteenth embodiment may be similar to the corresponding components of the seventh embodiment.

The configuration of the second light blocking unit 12 may be changed as in the thirteenth embodiment. In this case, effects similar to those of the seventh embodiment can also be achieved.

### Fourteenth Embodiment

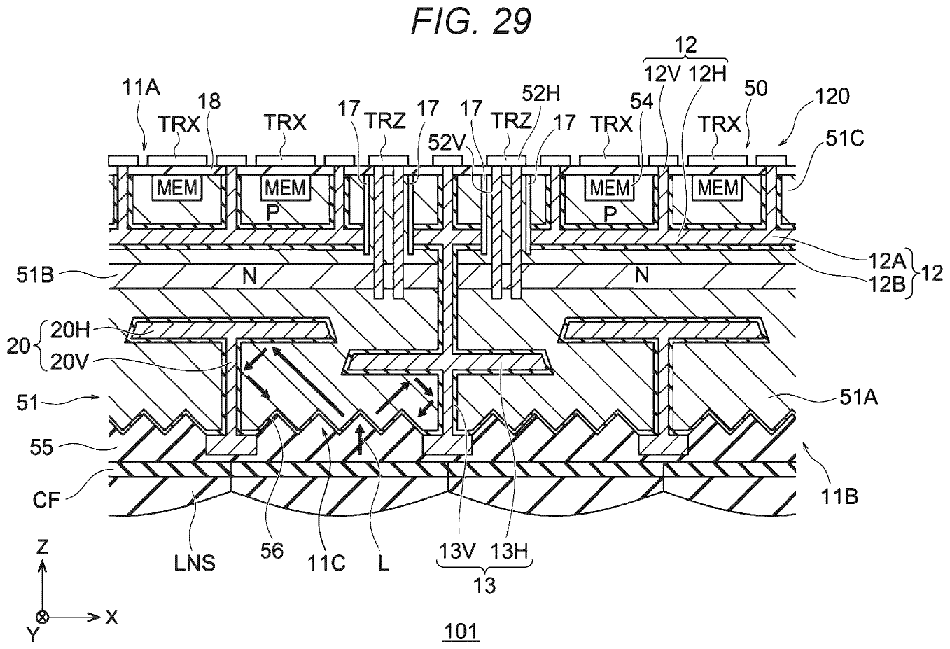

FIG. 29 is a cross-sectional view illustrating an example of the configuration of an imaging device 101 according to a fourteenth embodiment. The fourteenth embodiment differs from the eleventh embodiment (see FIG. 26) in that the element isolating portions 20 each include a vertical light blocking portion 20V and a horizontal light blocking portion 20H. The other components of the fourteenth embodiment may be similar to the corresponding components of the eleventh embodiment.

The vertical light blocking portions 20V extend in the depth direction of the semiconductor substrate 11. The horizontal light blocking portions 20H extend in the horizontal direction of the semiconductor substrate 11.

Reflective portions according to the fourteenth embodiment include the horizontal light blocking portions 12H, 13H, and 20H. In the present specification, the horizontal light blocking portions 20H are sometimes referred to as the second reflective portions.

The horizontal light blocking portions 20H (second reflective portions) are disposed at positions different from the transfer transistors TRZ (vertical gate electrodes 52V) when viewed from the Z direction. The horizontal light blocking portions 20H are provided so as to extend substantially parallel to the back surface 11B. Further, in the example illustrated in FIG. 29, the horizontal light blocking portions 20H are disposed in the photoelectric conversion units 51 (N⁻-type semiconductor region 51A).

The horizontal light blocking portions 20H are located between the vertical light blocking portions 20V and the horizontal light blocking portion 12H, and are connected to the tip portions of the vertical light blocking portions 20V. The horizontal light blocking portions 20H are disposed at positions closer to the front surface 11A than the horizontal light blocking portions 20H from the back surface 11B. Further, when viewed from the X direction, the end portions of the horizontal light blocking portions 20H may extend in the X direction so as to overlap the end portions of the horizontal light blocking portions 13H. That is, the horizontal light blocking portions 20H and the horizontal light blocking portions 13H are not connected, but may be alternately disposed in the X direction. With this arrangement, it is possible to prevent the incident light from directly entering the side of the TRZ 52 while securing the charge path between the horizontal light blocking portions 13H and the horizontal light blocking portions 20H.

The element isolating portions 20 may include the vertical light blocking portions 20V and the horizontal light blocking portions 20H, as in the fourteenth embodiment. In this case, effects similar to those of the eleventh embodiment can also be achieved.

### Fifteenth Embodiment

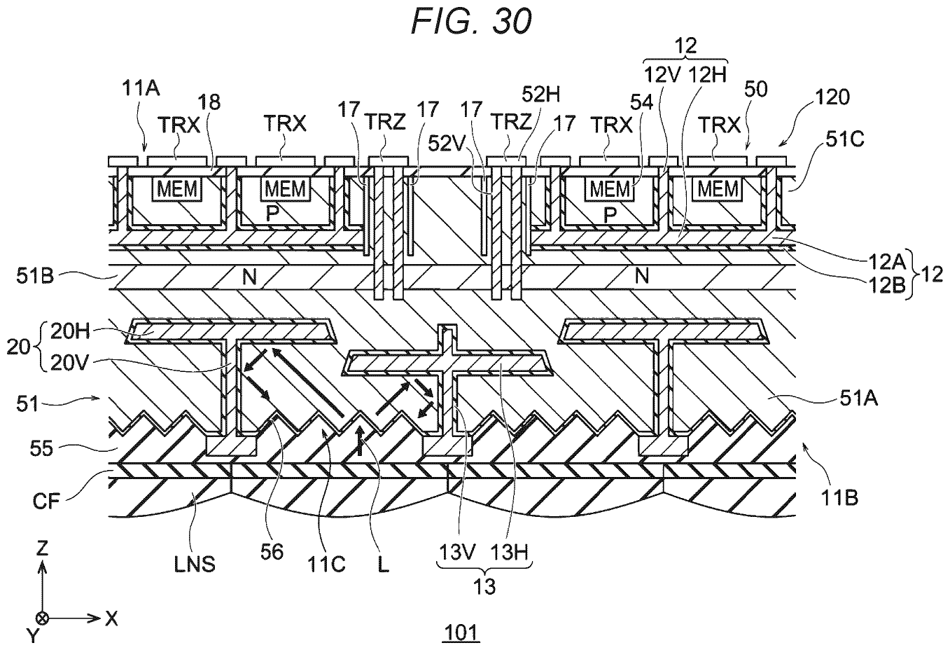

FIG. 30 is a cross-sectional view illustrating an example of the configuration of an imaging device 101 according to a fifteenth embodiment. The fifteenth embodiment differs from the fourteenth embodiment (see FIG. 29) in that the second light blocking unit 12 immediately above the first light blocking unit 13 is not provided, and the vertical light blocking portions 13V protrude from the horizontal light blocking portions 13H. The other components of the fifteenth embodiment may be similar to the corresponding components of the fourteenth embodiment.

Although the second light blocking unit 12 immediately above the first light blocking unit 13 is not provided, the vertical light blocking portions 13V protrude from the horizontal light blocking portions 13H, so that crosstalk between pixels can be reduced.

The configurations of the first light blocking unit 13 and the second light blocking unit 12 may be changed as in the fifteenth embodiment. In this case, effects similar to those of the fourteenth embodiment can also be achieved.

### Sixteenth Embodiment

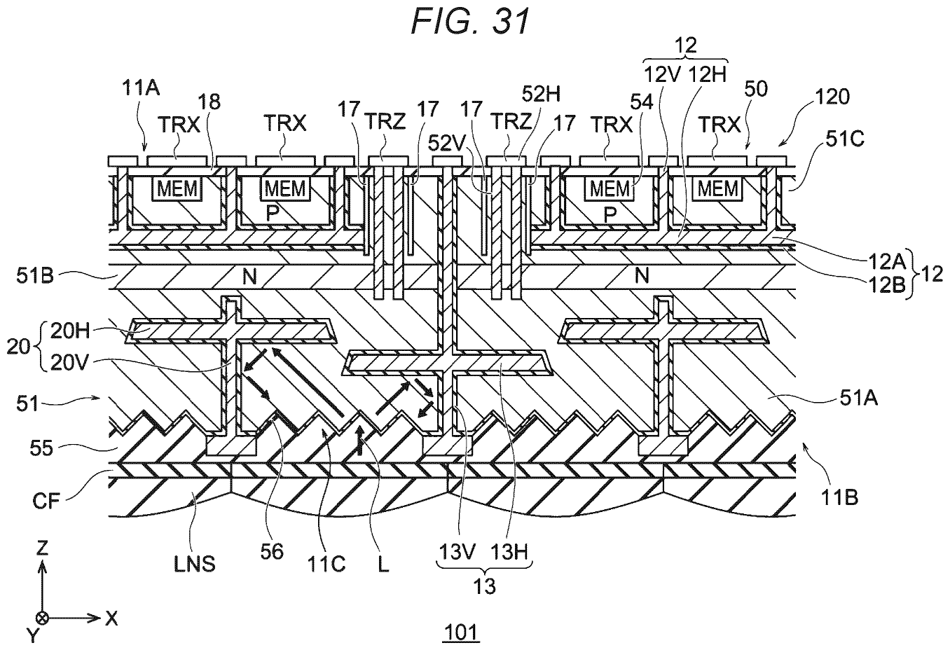

FIG. 31 is a cross-sectional view illustrating an example of the configuration of an imaging device 101 according to a sixteenth embodiment. The sixteenth embodiment differs from the fourteenth embodiment (see FIG. 29) in that the horizontal light blocking portion 12H immediately above the first light blocking unit 13 is not provided, and the vertical light blocking portions 20V protrude from the horizontal light blocking portions 20H. The other components of the sixteenth embodiment may be similar to the corresponding components of the fourteenth embodiment.

As the vertical light blocking portions 20V protrude from the horizontal light blocking portions 20H, blooming can be reduced.

The configurations of the second light blocking unit 12 and the element isolating portions 20 may be changed as in the sixteenth embodiment. In this case, effects similar to those of the fourteenth embodiment can also be achieved.

### Seventeenth Embodiment

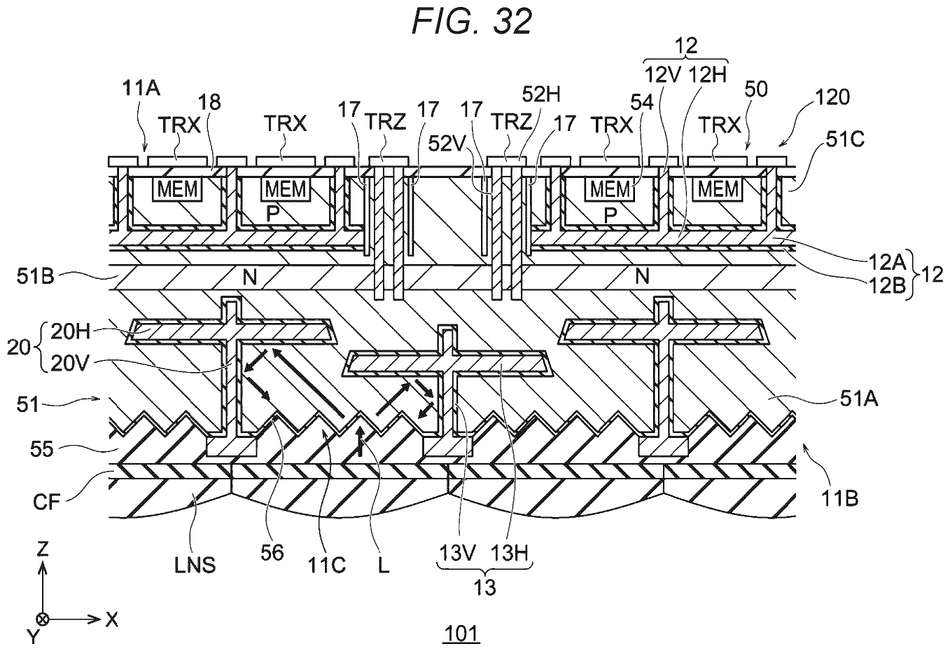

FIG. 32 is a cross-sectional view illustrating an example of the configuration of an imaging device 101 according to a seventeenth embodiment. In the seventeenth embodiment, the second light blocking unit 12 immediately above the first light blocking unit 13 is not provided, and the vertical light blocking portions 13V protrude from the horizontal light blocking portions 13H. Also, the vertical light blocking portions 20V protrude from the horizontal light blocking portions 20H. Accordingly, the seventeenth embodiment is a combination of the eleventh embodiment (see FIG. 30) and the sixteenth embodiment (see FIG. 31).

### Eighteenth Embodiment

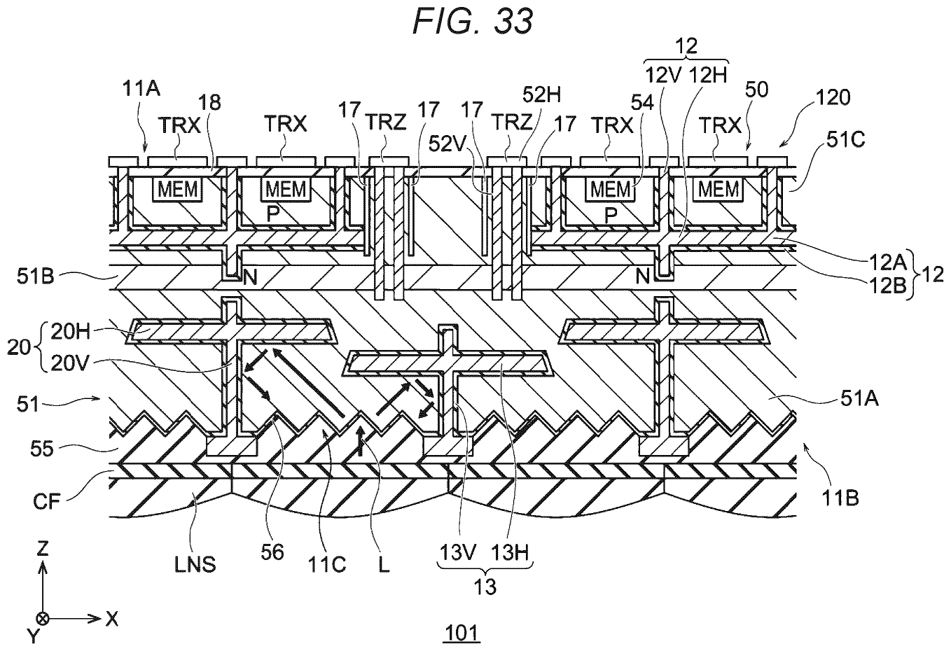

FIG. 33 is a cross-sectional view illustrating an example of the configuration of an imaging device 101 according to an eighteenth embodiment. The eighteenth embodiment differs from the seventeenth embodiment (see FIG. 32) in that the vertical light blocking portions 12V immediately above the element isolating portions 20 protrude from the horizontal light blocking portion 12H. The other components of the eighteenth embodiment may be similar to the corresponding components of the seventeenth embodiment. Note that a distance is provided between the lower ends of the vertical light blocking portions 12V and the element isolating portions 20.

With the vertical light blocking portions 12V protruding from the horizontal light blocking portion 12H, blooming can be reduced.

The configuration of the second light blocking unit 12 may be changed as in the eighteenth embodiment. In this case, effects similar to those of the seventeenth embodiment can also be achieved.

### Nineteenth Embodiment

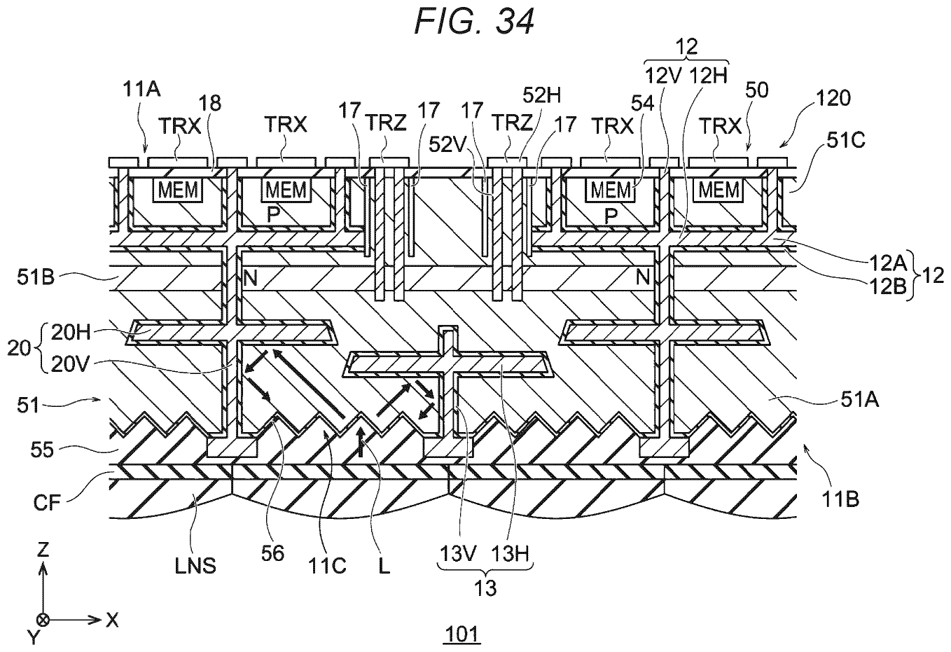

FIG. 34 is a cross-sectional view illustrating an example of the configuration of an imaging device 101 according to a nineteenth embodiment. The nineteenth embodiment differs from the fifteenth embodiment (see FIG. 30) in that the vertical light blocking portions 12V and 20V are provided and penetrate the semiconductor substrate 11. The other components of the nineteenth embodiment may be similar to the corresponding components of the fifteenth embodiment.

As the vertical light blocking portions 12V and 20V are provided and penetrate the semiconductor substrate 11, blooming can be reduced, and crosstalk between pixels can also be reduced.

The configurations of the second light blocking unit 12 and the element isolating portions 20 may be changed as in the nineteenth embodiment. In this case, effects similar to those of the fifteenth embodiment can also be achieved.

### Twentieth Embodiment

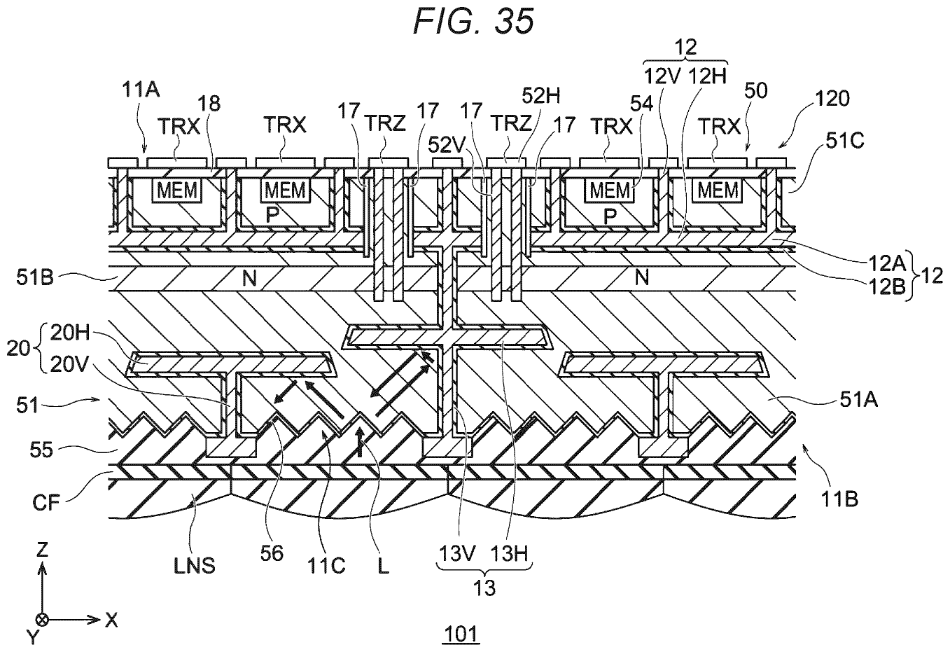

FIG. 35 is a cross-sectional view illustrating an example of the configuration of an imaging device 101 according to a twentieth embodiment. In the twentieth embodiment, the height relationship between the horizontal light blocking portions 13H and the horizontal light blocking portions 20H is opposite to that of the fourteenth embodiment (see FIG. 29). Therefore, the horizontal light blocking portions 13H are provided at positions closer to the front surface 11A than the horizontal light blocking portions 20H. The other components of the twentieth embodiment may be similar to the corresponding components of the fourteenth embodiment.

The configurations of the first light blocking unit 13 and the element isolating portions 20 may be changed as in the twentieth embodiment. In this case, effects similar to those of the fourteenth embodiment can also be achieved.

### Twenty-First Embodiment

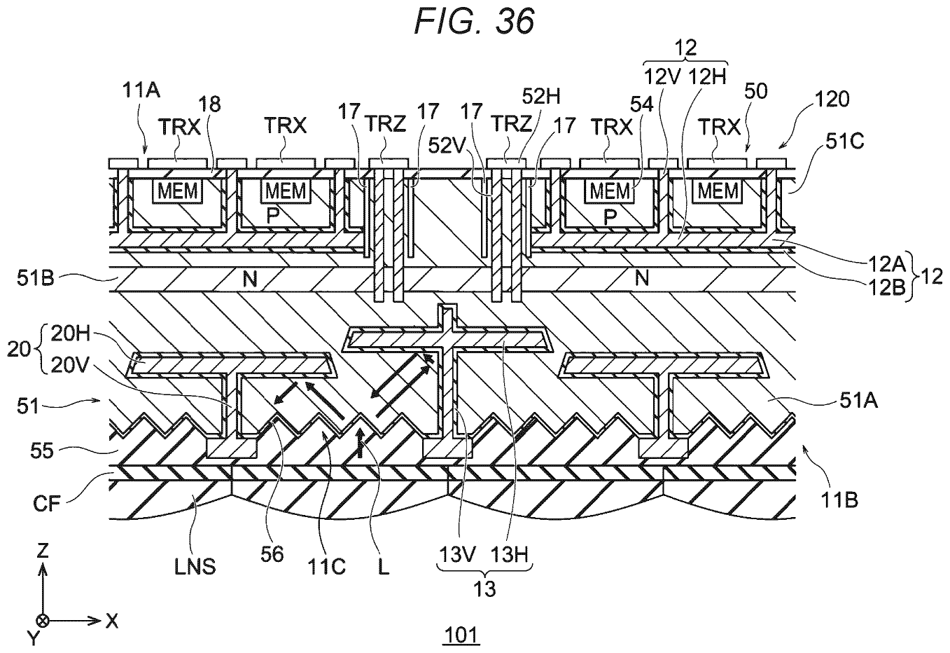

FIG. 36 is a cross-sectional view illustrating an example of the configuration of an imaging device 101 according to a twenty-first embodiment. In the twenty-first embodiment, the height relationship between the horizontal light blocking portions 13H and the horizontal light blocking portions 20H is opposite to that of the fifteenth embodiment (see FIG. 30). Therefore, the horizontal light blocking portions 13H are provided at positions closer to the front surface 11A than the horizontal light blocking portions 20H. The other components of the twenty-first embodiment may be similar to the corresponding components of the fifteenth embodiment.

The configurations of the first light blocking unit 13 and the element isolating portions 20 may be changed as in the twenty-first embodiment. In this case, effects similar to those of the fifteenth embodiment can also be achieved.

### Twenty-Second Embodiment

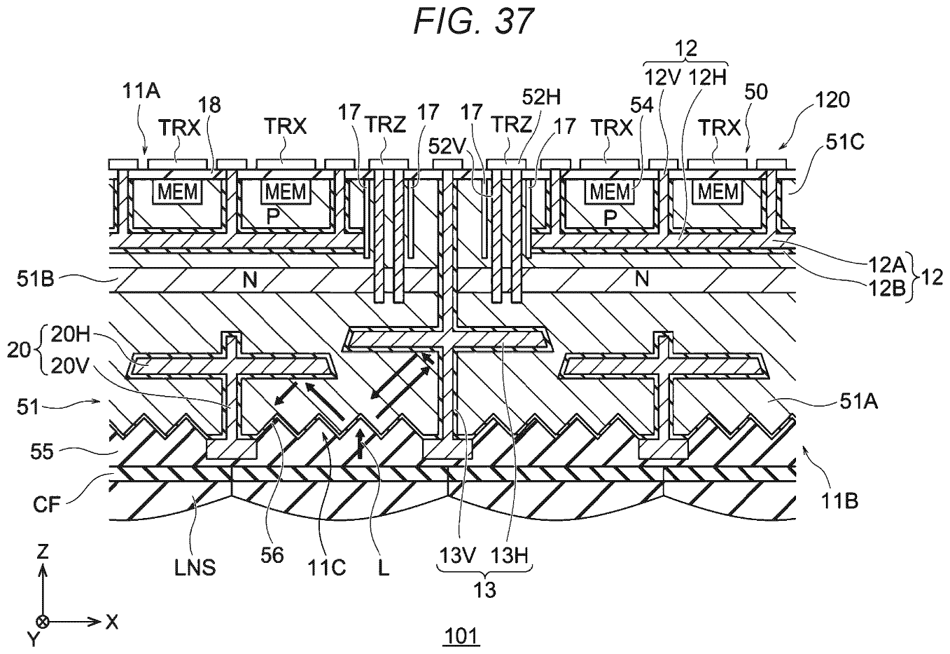

FIG. 37 is a cross-sectional view illustrating an example of the configuration of an imaging device 101 according to a twenty-second embodiment. In the twenty-second embodiment, the height relationship between the horizontal light blocking portions 13H and the horizontal light blocking portions 20H is opposite to that of the sixteenth embodiment (see FIG. 31). Therefore, the horizontal light blocking portions 13H are provided at positions closer to the front surface 11A than the horizontal light blocking portions 20H. The other components of the twenty-second embodiment may be similar to the corresponding components of the sixteenth embodiment.

The configurations of the first light blocking unit 13 and the element isolating portions 20 may be changed as in the twenty-second embodiment. In this case, effects similar to those of the sixteenth embodiment can also be achieved.

### Twenty-Third Embodiment

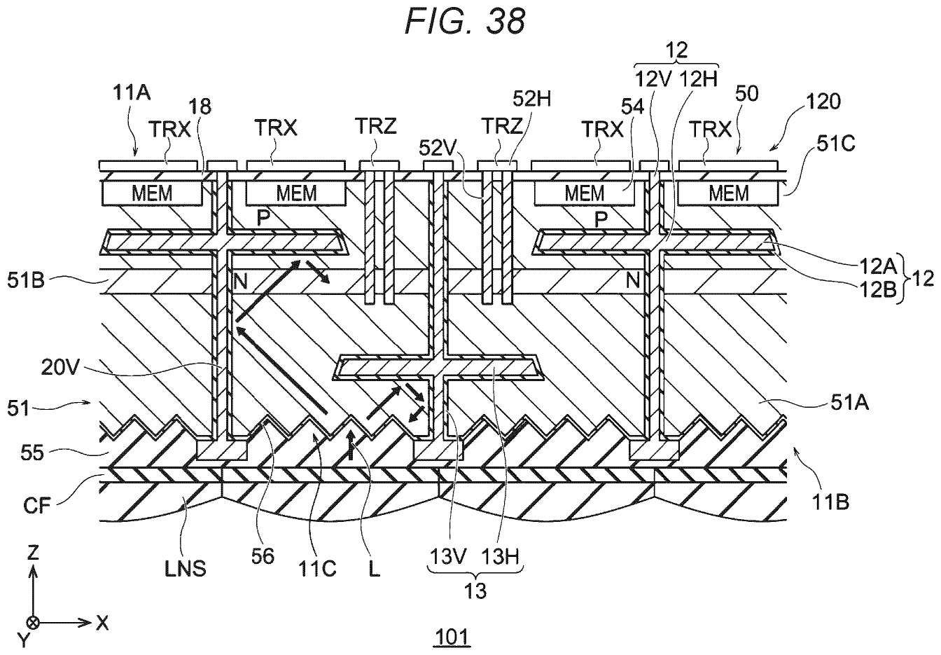

FIG. 38 is a cross-sectional view illustrating an example of the configuration of an imaging device 101 according to a twenty-third embodiment. The twenty-third embodiment differs from the seventh embodiment (see FIG. 22) in that the etching stoppers 17 are not provided.

Since the etching stoppers 17 are not provided, the shapes of the right and left end surfaces of the horizontal light blocking portion 12H are formed by wet etching until the (111) plane is exposed. Therefore, the right and left end surfaces of the horizontal light blocking portion 12H are inclined with respect to the Z direction, like the right and left end surfaces of the horizontal light blocking portions 13H and 20H. The horizontal light blocking portion 12H is provided so as to cover the charge retaining units (MEM) 54, as viewed from the Z direction.

Furthermore, in the example illustrated in FIG. 38, the number of vertical light blocking portions 12V is smaller than that in the first embodiment in FIG. 4. By reducing the vertical light blocking portions 12V, it is possible to further miniaturize the pixels.

The other components of the twenty-third embodiment may be similar to the corresponding components of the seventh embodiment.

As in the twenty-third embodiment, the etching stoppers 17 may not be provided. In this case, effects similar to those of the nineteenth embodiment can also be achieved.

### Twenty-Fourth Embodiment

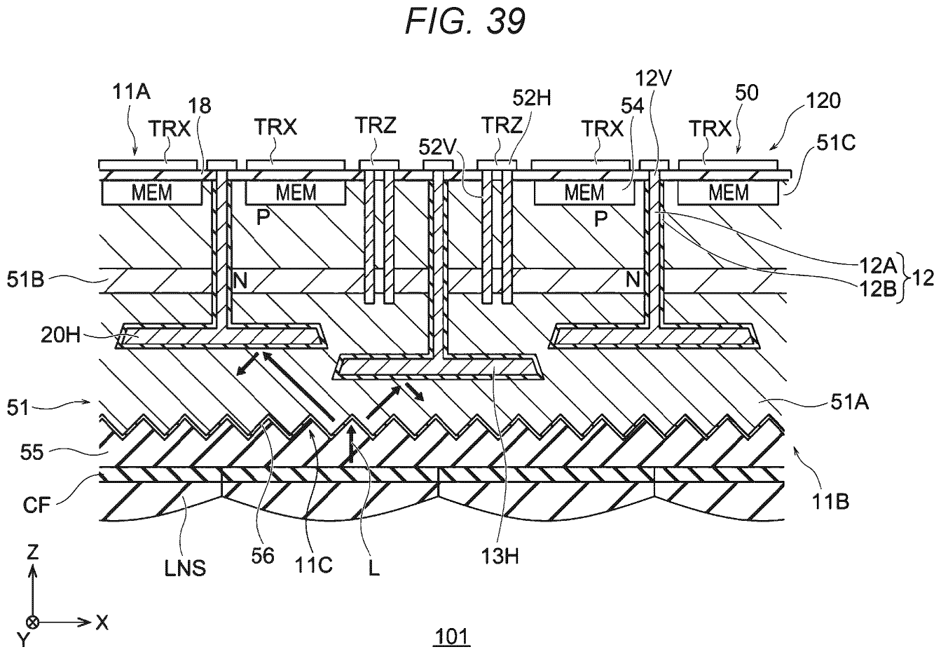

FIG. 39 is a cross-sectional view illustrating an example of the configuration of an imaging device 101 according to a twenty-fourth embodiment. The twenty-fourth embodiment differs from the twenty-third embodiment (see FIG. 38) in that the horizontal light blocking portions 20H are provided, and the vertical light blocking portions 13V between the horizontal light blocking portions 13H and the back surface 11B, the vertical light blocking portions 20V between the horizontal light blocking portions 20H and the back surface 11B, and the horizontal light blocking portion 12H are not provided. The other components of the twenty-fourth embodiment may be similar to the corresponding components of the twenty-third embodiment.

Note that, in the example illustrated in FIG. 39, the horizontal light blocking portions 13H and 20H are formed from the side of the front surface 11A.

The configurations of the first light blocking unit 13, the second light blocking unit 12, and the element isolating portions 20 may be changed as in the twenty-fourth embodiment. In this case, effects similar to those of the twenty-third embodiment can also be achieved.

### Twenty-Fifth Embodiment

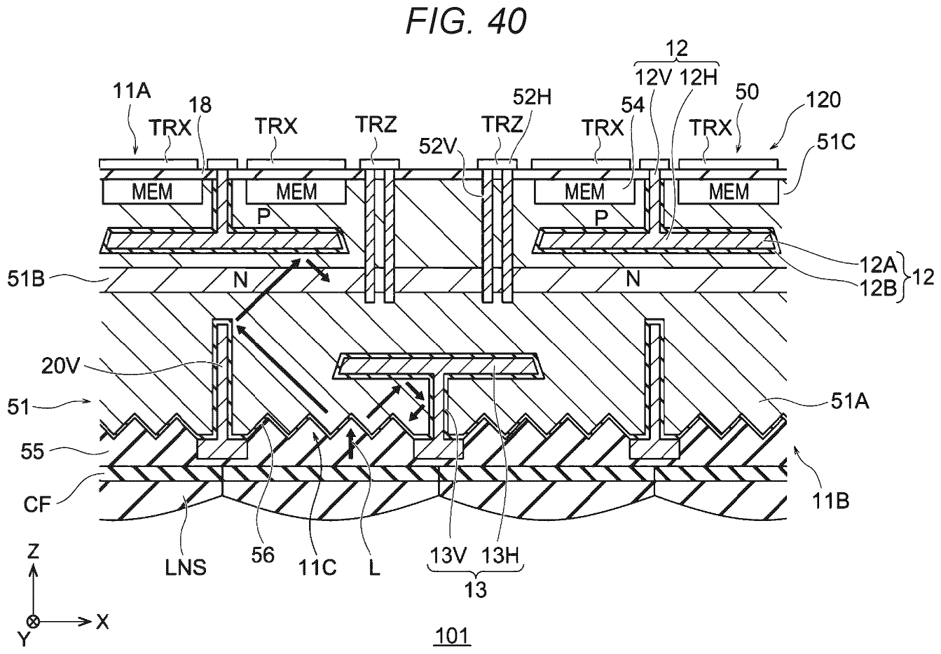

FIG. 40 is a cross-sectional view illustrating an example of the configuration of an imaging device 101 according to a twenty-fifth embodiment. The twenty-fifth embodiment differs from the twenty-third embodiment (see FIG. 38) in that the vertical light blocking portions 13V above the horizontal light blocking portions 13H are not provided, and the vertical light blocking portions 20V do not reach the second light blocking unit 12. The other components of the twenty-fifth embodiment may be similar to the corresponding components of the twenty-third embodiment.

The configurations of the first light blocking unit 13 and the element isolating portions 20 may be changed as in the twenty-fifth embodiment. In this case, effects similar to those of the twenty-third embodiment can also be achieved.

### Twenty-Sixth Embodiment

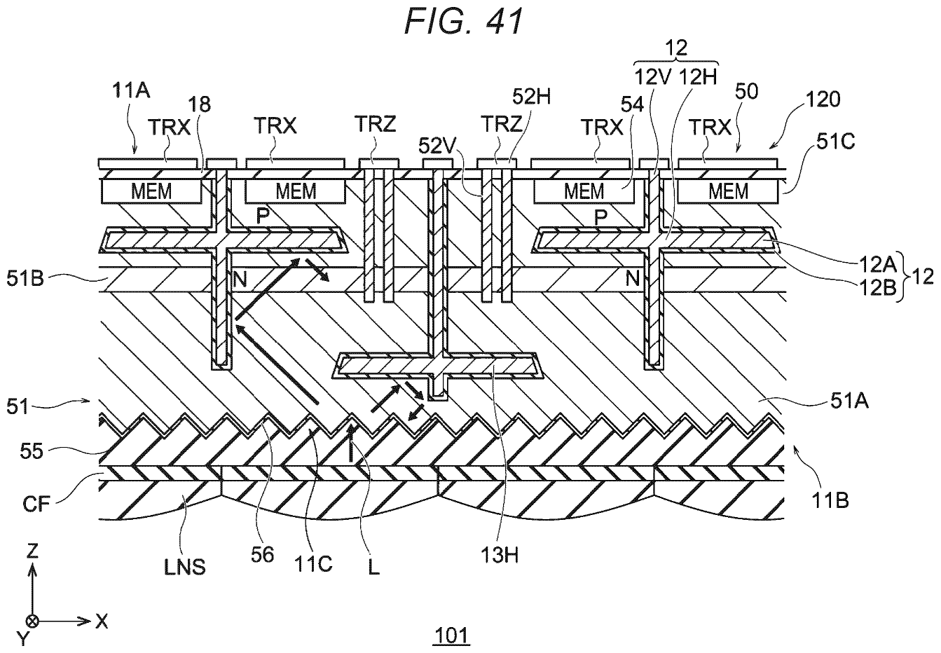

FIG. 41 is a cross-sectional view illustrating an example of the configuration of an imaging device 101 according to a twenty-sixth embodiment. The twenty-sixth embodiment differs from the twenty-fourth embodiment (see FIG. 39) in that the vertical light blocking portions 12V protrude from the horizontal light blocking portions 13H, the horizontal light blocking portion 12H is provided, and the horizontal light blocking portions 20H are not provided. The other components of the twenty-sixth embodiment may be similar to the corresponding components of the twenty-fourth embodiment. Note that a distance is provided between the lower ends of the vertical light blocking portions 12V and the back surface 11B.

The configurations of the second light blocking unit 12 and the element isolating portions 20 may be changed as in the twenty-sixth embodiment. In this case, effects similar to those of the twenty-fourth embodiment can also be achieved.

### Twenty-Seventh Embodiment

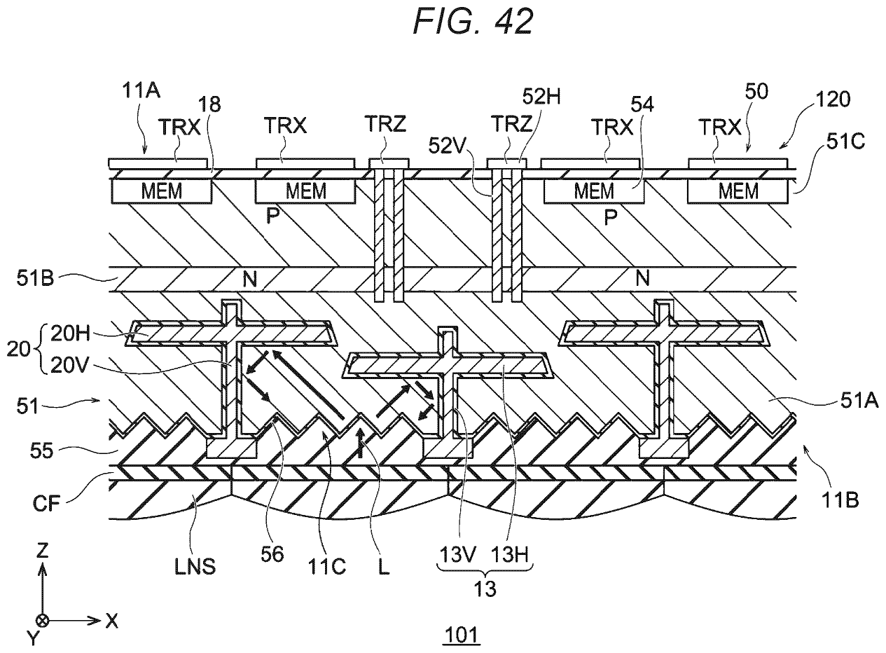

FIG. 42 is a cross-sectional view illustrating an example of the configuration of an imaging device 101 according to a twenty-seventh embodiment. The twenty-seventh embodiment differs from the twenty-fifth embodiment (see FIG. 40) in that the vertical light blocking portions 13V protrude from the horizontal light blocking portions 13H, the horizontal light blocking portions 20H are provided, and the second light blocking unit 12 is not provided. The other components of the twenty-seventh embodiment may be similar to the corresponding components of the twenty-fifth embodiment.

The configurations of the first light blocking unit 13, the second light blocking unit 12, and the element isolating portions 20 may be changed as in the twenty-seventh embodiment. In this case, effects similar to those of the twenty-fifth embodiment can also be achieved.

### Twenty-Eighth Embodiment

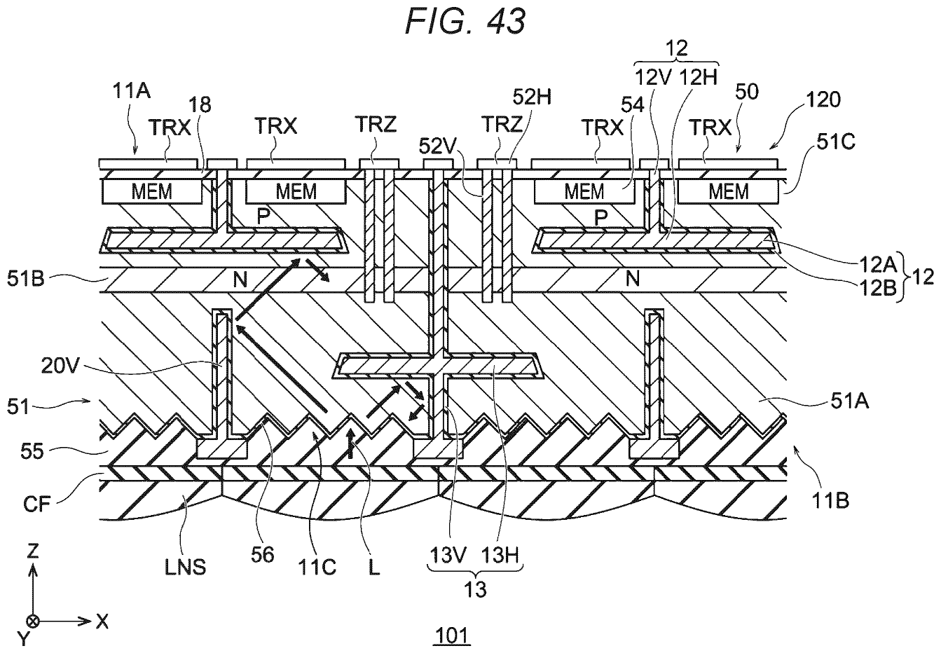

FIG. 43 is a cross-sectional view illustrating an example of the configuration of an imaging device 101 according to a twenty-eighth embodiment. The twenty-eighth embodiment differs from the twenty-third embodiment (see FIG. 38) in that the vertical light blocking portions 20V do not reach the second light blocking unit 12. The other components of the twenty-eighth embodiment may be similar to the corresponding components of the twenty-third embodiment.

The configuration of the element isolating portions 20 may be changed as in the twenty-eighth embodiment. In this case, effects similar to those of the twenty-third embodiment can also be achieved.

### Twenty-Ninth Embodiment

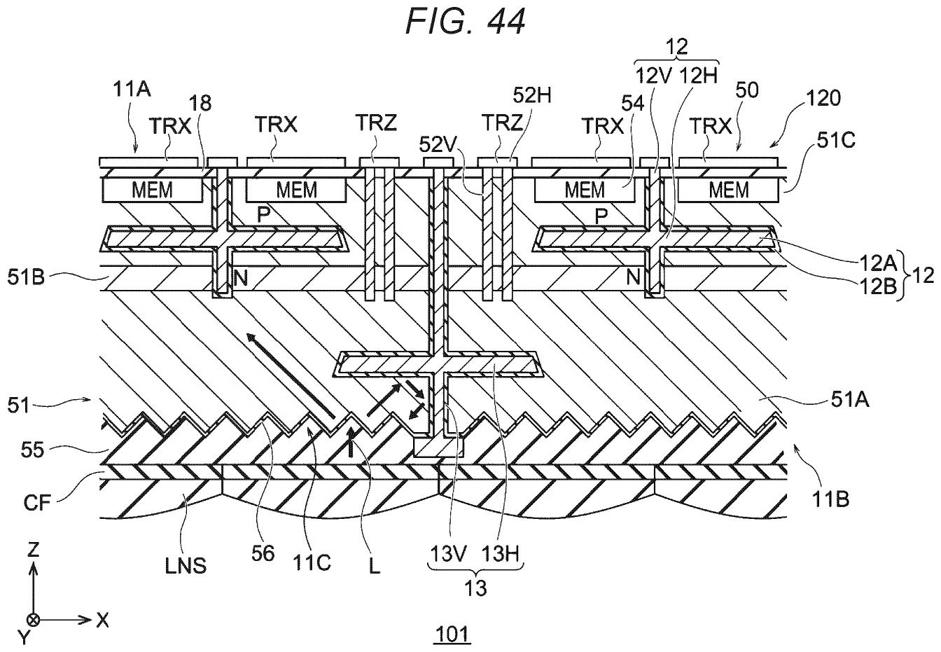

FIG. 44 is a cross-sectional view illustrating an example of the configuration of an imaging device 101 according to a twenty-ninth embodiment. The twenty-ninth embodiment differs from the twenty-third embodiment (see FIG. 38) in that the element isolating portions 20 are not provided. The other components of the twenty-ninth embodiment may be similar to the corresponding components of the twenty-third embodiment.

The configuration of the element isolating portions 20 may be changed as in the twenty-ninth embodiment. In this case, effects similar to those of the twenty-third embodiment can also be achieved.

### Thirtieth Embodiment

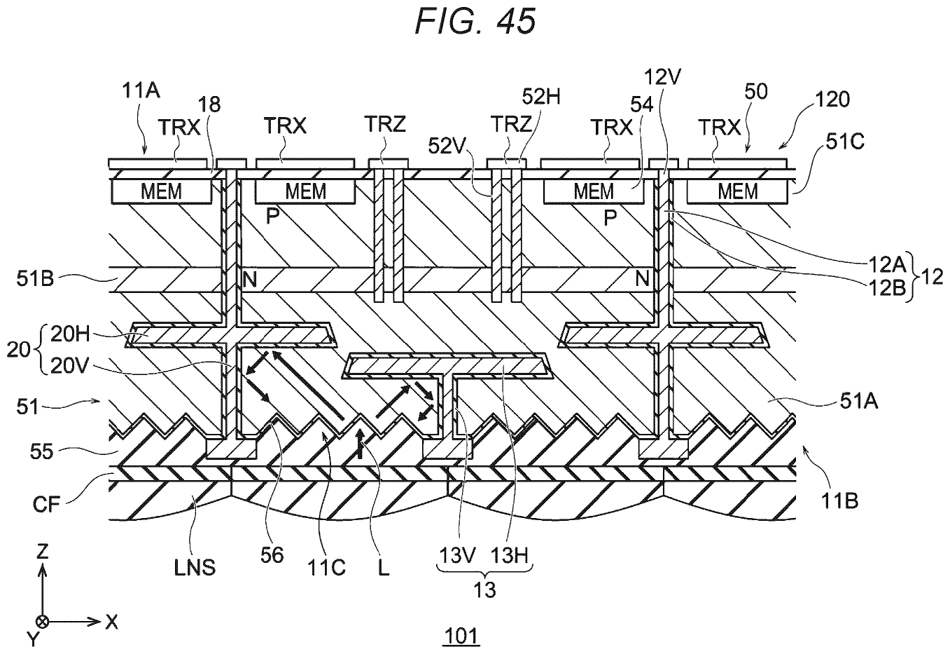

FIG. 45 is a cross-sectional view illustrating an example of the configuration of an imaging device 101 according to a thirtieth embodiment. The thirtieth embodiment differs from the twenty-third embodiment (see FIG. 38) in that the horizontal light blocking portions 20H are provided, and the horizontal light blocking portion 12H and the vertical light blocking portions 12V and 13V above the horizontal light blocking portions 13H are not provided. The other components of the thirtieth embodiment may be similar to the corresponding components of the twenty-third embodiment.

The configurations of the first light blocking unit 13, the second light blocking unit 12, and the element isolating portions 20 may be changed as in the thirtieth embodiment. In this case, effects similar to those of the twenty-third embodiment can also be achieved.

### Thirty-First Embodiment

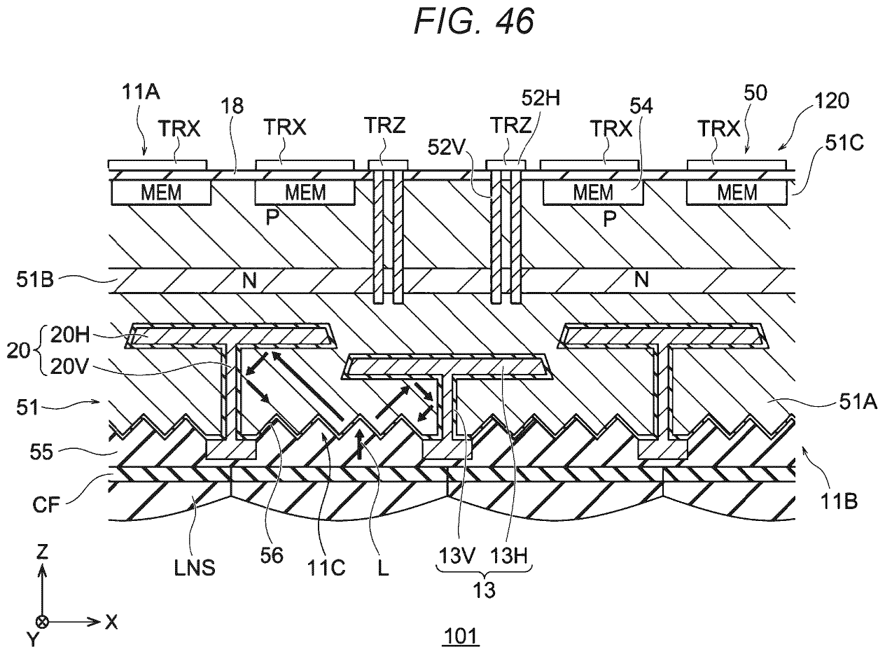

FIG. 46 is a cross-sectional view illustrating an example of the configuration of an imaging device 101 according to a thirty-first embodiment. The thirty-first embodiment differs from the thirtieth embodiment (see FIG. 45) in that the second light blocking unit 12 is not provided, and the vertical light blocking portions 20V do not protrude from the horizontal light blocking portions 20H. The other components of the thirtieth embodiment may be similar to the corresponding components of the thirtieth embodiment.

The configurations of the second light blocking unit 12 and the element isolating portions 20 may be changed as in the thirty-first embodiment. In this case, effects similar to those of the thirtieth embodiment can also be achieved.

### (Other Modifications)

The Si (111) substrate in the present disclosure is a substrate or a wafer that is formed with a silicon single crystal and has a crystal plane represented by (111) in the notation of the Miller indices. The Si (111) substrate in the present disclosure also includes a substrate or a wafer whose crystal orientation is shifted by several degrees, or, for example, is shifted by several degrees from the (111) plane in the [110] direction that is the closest. Further, a silicon single crystal grown by an epitaxial method or the like on part or the entire surface of any of these substrates or wafers is also included.

Further, in the notation adopted in the present disclosure, the plane index (111) is a generic term for a (111) plane, a (−111) plane, a (1-11) plane, a (11-1) plane, a (−1-11) plane, a (−11-1) plane, a (1-1-1) plane, and a (−1-1-1) plane, which are crystal planes equivalent to one another in symmetry. Therefore, the Si (111) substrate in the specification and the like of the present disclosure may be replaced with a Si (1-11) substrate, for example. Here, the minus sign is substituted for the bar sign for representing an index of the Miller indices in the negative direction.

Meanwhile, the <110> direction in the description of the present disclosure is a generic term for a direction, a [101] direction, a [011] direction, a [−110] direction, a [1-10] direction, a [−101] direction, a [10-1] direction, a [0-11] direction, a [01-1] direction, a [−1-10] direction, a [−10-1] direction, and a [0-1-1] direction, which are crystal plane directions equivalent to one another in symmetry, and the <110> direction may be replaced with any one of these directions. However, in the present disclosure, etching is to be performed in a direction orthogonal to the element formation plane, and in a direction further orthogonal to the direction orthogonal to the element formation plane (which is a direction parallel to the element formation plane).

Table 1 shows specific combinations of a plane and an orientation in which etching in the <110> direction is possible in the (111) plane, which is a crystal plane of the Si (111) substrate in the present disclosure.

TABLE 1

| Etching | Element formation plane | | | | | | | |
|---|---|---|---|---|---|---|---|---|
| orientation | (111) | (-111) | (1-11) | (11-1) | (-1-11) | (-11-1) | (1-1-1) | (-1-1-1) |
| [110] | | ◯ | ◯ | | | ◯ | ◯ | |
| [101] | | ◯ | | ◯ | ◯ | | ◯ | |
| [011] | | | ◯ | ◯ | ◯ | ◯ | | |
| [-110] | ◯ | | | ◯ | ◯ | | | ◯ |
| [1-10] | ◯ | | | ◯ | ◯ | | | ◯ |
| [-101] | ◯ | | ◯ | | | ◯ | | ◯ |
| [10-1] | ◯ | | ◯ | | | ◯ | | ◯ |
| [0-11] | ◯ | ◯ | | | | | ◯ | ◯ |
| [01-1] | ◯ | ◯ | | | | | ◯ | ◯ |
| [-1-10] | | ◯ | ◯ | | | ◯ | ◯ | |
| [-10-1] | | ◯ | | ◯ | ◯ | | ◯ | |
| [0-1-1] | | | ◯ | ◯ | ◯ | ◯ | | |

As shown in Table 1, there are 96 (=8×12) combinations of a plane index (111) and a <110> direction. However, the <110> direction in the present disclosure is limited to a direction orthogonal to the plane index (111), which is the element formation plane, and a direction parallel to the element formation plane. That is, the combination of the element formation plane in the Si (111) substrate of the present disclosure and the orientation in which etching is performed on the Si (111) substrate is selected from among the combinations indicated by ∘ in Table 1.

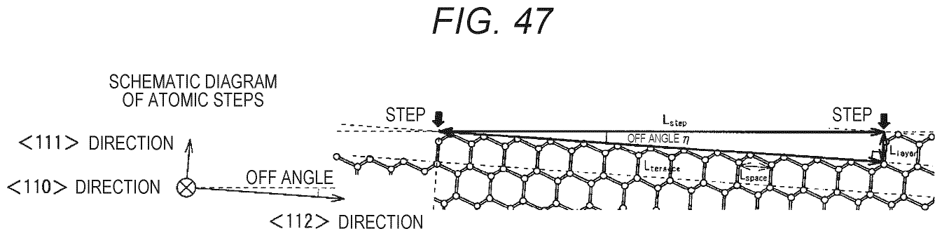

Furthermore, the Si (111) substrate also includes a case of a substrate processed so that the substrate surface has an off angle with respect to the <112> direction as illustrated in FIG. 47, for example. In a case where the off angle is 19.47° or smaller, and, in a case where the substrate has an off angle, the relationship is also maintained such that the etching rate in the <110> direction, which is a direction in which there is one Si back bond, is sufficiently higher than the etching rate in the <111> direction, which is a direction in which there are three Si back bonds. When the off angle is greater, the number of steps is larger, and the density of micro steps is higher. Therefore, the off angle is preferably 5° or smaller. Note that, although a case where the substrate surface has an off angle in the <112> direction is illustrated in the example in FIG. 47, there may be an off angle in the <110> direction, and the direction of the off angle is not limited to any particular direction. Furthermore, the Si plane orientation can be analyzed by an X-ray diffraction method, an electron beam diffraction method, an electron beam backscattering diffraction method, or the like. Since the number of Si back bonds is determined by the crystal structure of Si, the number of back bonds can also be analyzed by analyzing the Si plane orientation.

### <Example Application to an Electronic Apparatus>

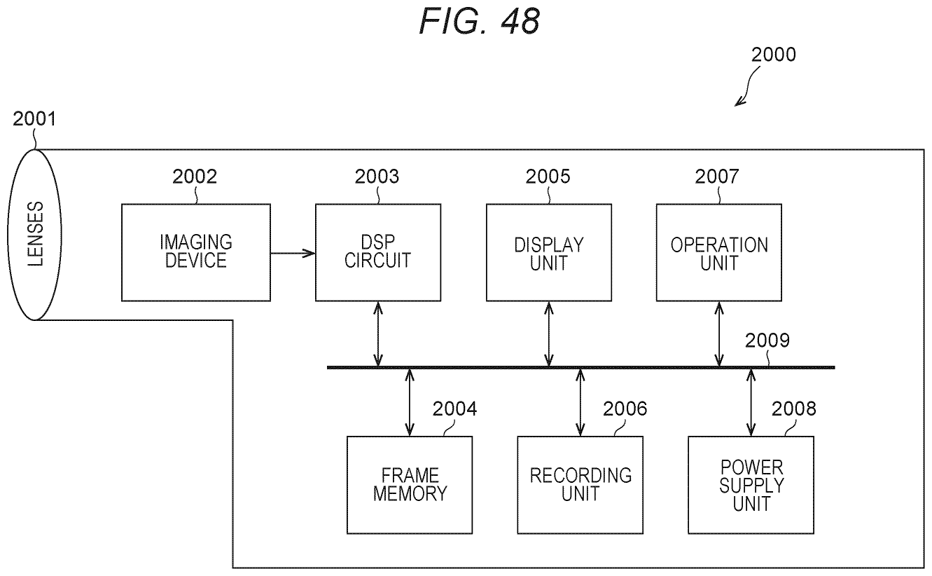

FIG. 48 is a block diagram illustrating an example configuration of a camera 2000 as an electronic apparatus to which the present technology is applied.

The camera 2000 includes an optical unit 2001 formed with a lens group and the like, an imager (imaging device) 2002 to which the above-described imaging device 101 or the like (hereinafter referred to as the imaging device 101 or the like) is applied, and a digital signal processor (DSP) circuit 2003 that is a camera signal processing circuit. Also, the camera 2000 includes a frame memory 2004, a display unit 2005, a recording unit 2006, an operation unit 2007, and a power supply unit 2008. The DSP circuit 2003, the frame memory 2004, the display unit 2005, the recording unit 2006, the operation unit 2007, and the power supply unit 2008 are connected to one another through a bus line 2009.

The optical unit 2001 captures incident light (image light) from the subject and forms an image on the imaging surface of the imaging device 2002. The imaging device 2002 converts the amount of the incident light from which an image is formed on the imaging surface by the optical unit 2001 into an electrical signal in units of pixels, and outputs the electrical signal as a pixel signal.

The display unit 2005 is formed with a panel type display device such as a liquid crystal panel or an organic EL panel, for example, and displays a moving image or a still image captured by the imaging device 2002. The recording unit 2006 records the moving image or the still image captured by the imaging device 2002 on a recording medium such as a hard disk or a semiconductor memory.

The operation unit 2007 issues operation commands for various functions of the camera 2000, in response to an operation performed by a user. The power supply unit 2008 supplies, as appropriate, various power sources serving as operation power sources for the DSP circuit 2003, the frame memory 2004, the display unit 2005, the recording unit 2006, and the operation unit 2007, to these supply targets.

As described above, the above-described imaging device 101 or the like is used as the imaging device 2002 so that acquisition of a preferred image can be expected.

### (Example Applications to Mobile Objects)

The technology according to the present disclosure (present technology) can be applied to various products. For example, the technology according to the present disclosure may also be embodied as a device that is mounted on any type of mobile object such as an automobile, an electric automobile, a hybrid electric automobile, a motorcycle, a bicycle, a personal mobility, an airplane, a drone, a ship, and a robot.

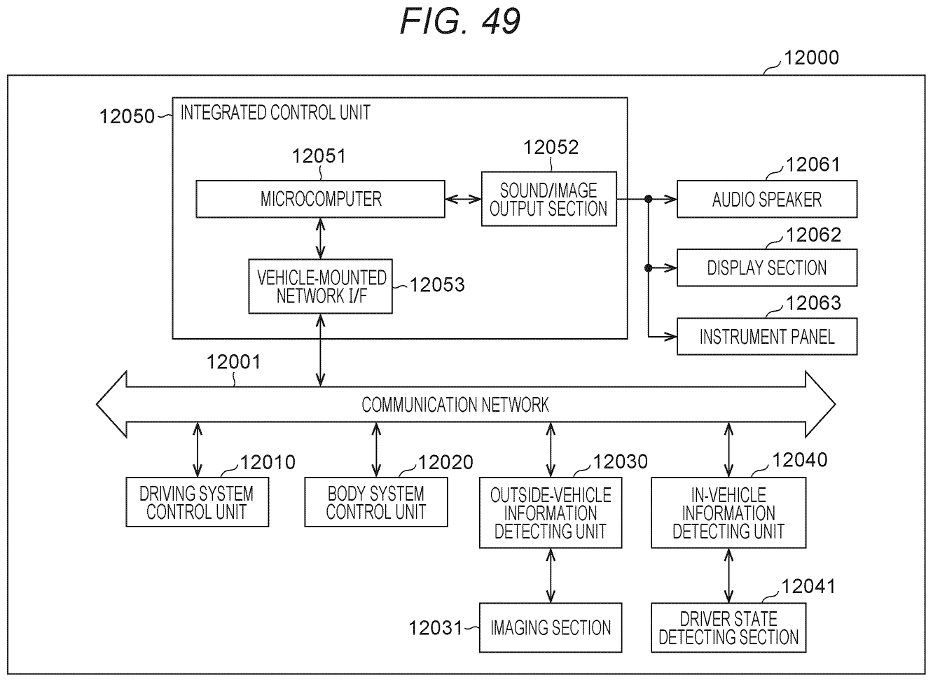

FIG. 49 is a block diagram illustrating an example of a schematic configuration of a vehicle control system that is an example of a mobile object control system to which the technology according to the present disclosure can be applied.

The vehicle control system 12000 includes a plurality of electronic control units connected to each other via a communication network 12001. In the example illustrated in FIG. 49, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 may output the control instruction to the body system control unit 12020 on the basis of the information outside the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 49, an audio speaker 12061, a display section 12062, and an instrument panel 12063 are illustrated as examples of output devices. The display section 12062 may, for example, include at least one of an on-board display and a head-up display.

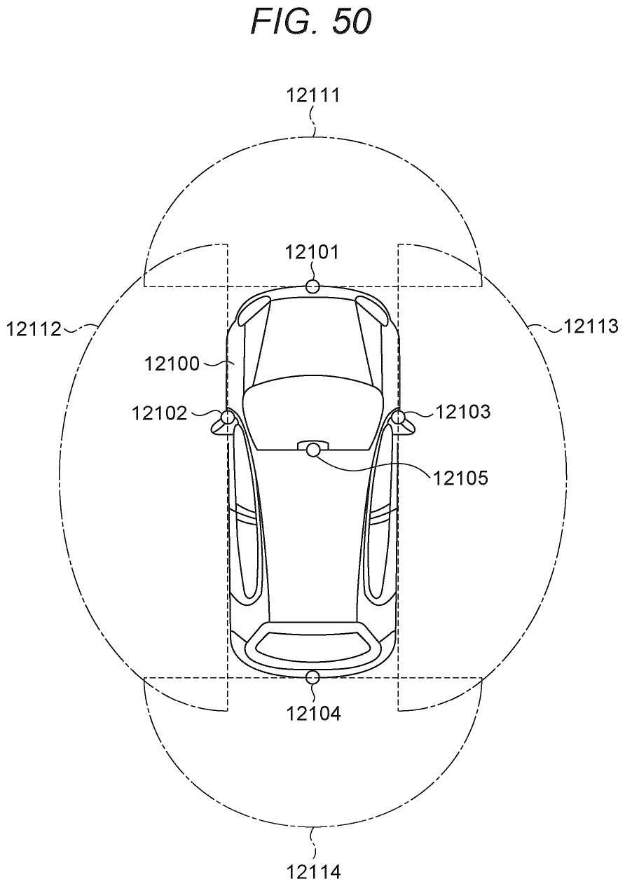

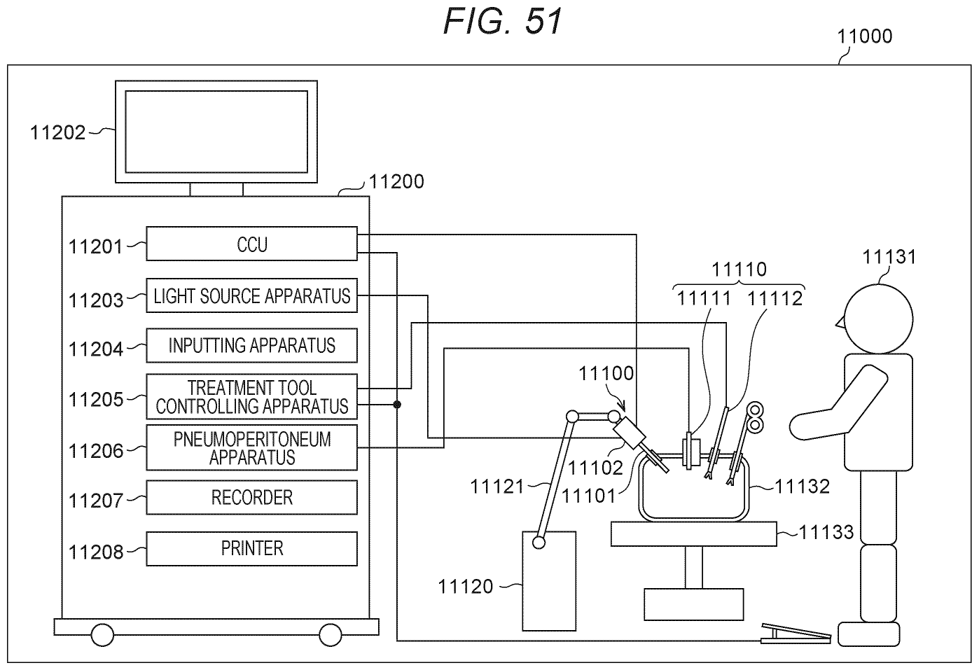

FIG. 50 is a diagram illustrating an example of the installation positions of the imaging sections 12031.

In FIG. 50, the imaging sections 12031 include imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 50 illustrates an example of the imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of a vehicle control system to which the technology according to the present disclosure can be applied has been described above. The technology according to the present disclosure may be applied to the imaging section 12031 among the components described above. Specifically, the imaging device 101 illustrated in FIG. 1 or the like can be applied to the imaging section 12031. By applying the technology according to the present disclosure to the imaging section 12031, it is possible to expect the vehicle control system to work in an excellent manner.

### <Example Application to an Endoscopic Surgery System>

The technology according to the present disclosure (present technology) can be applied to various products. For example, the technology according to the present disclosure may be applied to an endoscopic surgery system.

FIG. 51 is a diagram illustrating an example of a schematic configuration of an endoscopic surgery system to which the technology according to the present disclosure (present technology) can be applied.

FIG. 51 illustrates a state in which an operator (medical doctor) 11131 is performing surgery on a patient 11132 on a patient bed 11133, using an endoscopic surgery system 11000. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as a light emitting diode (LED), for example, and supplies irradiation light for imaging a surgical region or the like to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

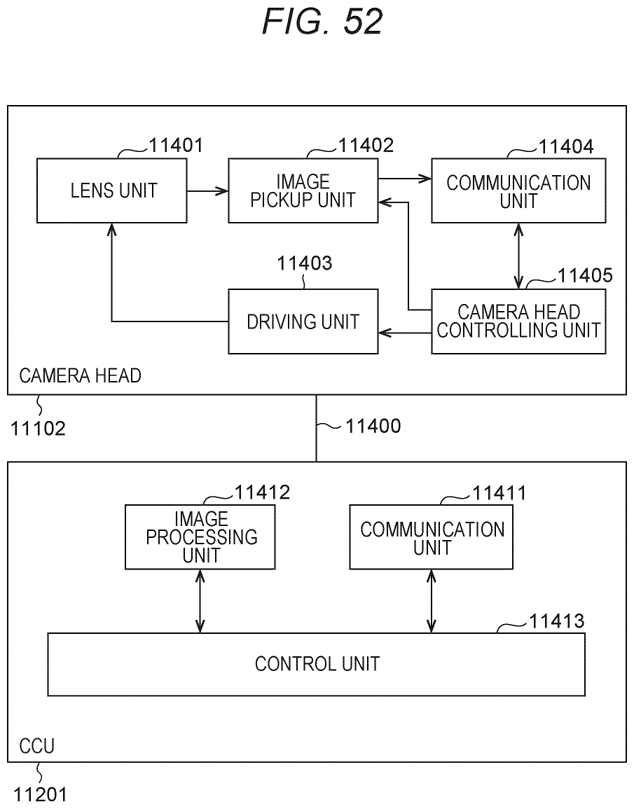

FIG. 52 is a block diagram illustrating an example of a functional configuration of the camera head 11102 and the CCU 11201 illustrated in FIG. 51.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. Alternatively, the image pickup unit 11402 may include a pair of image pickup elements for acquiring right-eye and left-eye image signals compatible with three-dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of an endoscopic surgery system to which the technology according to the present disclosure can be applied has been described above. The technology according to the present disclosure can be applied to the image pickup unit 11402 provided in the camera head 11102 of the endoscope 11100 among the components described above. By applying the technology according to the present disclosure to the image pickup unit 11402, it is possible to obtain a clearer image of a surgical region, and it is possible for the operator to check the surgical region without fail.

Note that an endoscopic surgery system has been described as an example herein, but the technology according to the present disclosure may be applied to a microscopic surgery system or the like, for example.

Note that the present technology can be embodied in the configurations as described below.

(1)

A solid-state imaging device including:
a semiconductor substrate including a first surface as a light receiving surface, and an uneven structure unit provided in the first surface;
a photoelectric conversion unit that is provided in the semiconductor substrate, and performs photoelectric conversion to generate electric charge corresponding to an amount of received light; and
a reflective portion that is provided in the semiconductor substrate so as to extend substantially parallel to the first surface, and reflects light that has passed through the first surface.

(2)

The solid-state imaging device according to (1), in which
the uneven structure unit includes a plurality of protrusions or a plurality of recesses, and
the protrusions or the recesses have a substantially polygonal outer shape as viewed from a normal direction of the first surface.

(3)

The solid-state imaging device according to (2), in which at least one side of the outer shape of the protrusion or the recess as viewed from the normal direction is inclined with respect to a pixel array direction.

(4)

The solid-state imaging device according to (3), in which
the protrusion or the recess has a shape of a substantially quadrangular pyramid, and
four sides of the outer shape of the protrusion or the recess as viewed from the normal direction are inclined by 45° with respect to the pixel array direction.

(5)

The solid-state imaging device according to (3), in which the protrusion or the recess has a shape of a substantially hexagonal pyramid.

(6)

The solid-state imaging device according to any one of (3) to (5), in which the pixel array direction is a direction in which an element isolating portion that isolates a plurality of pixels extends.

(7)

The solid-state imaging device according to any one of (3) to (6), in which
the semiconductor substrate is a silicon substrate,
the uneven structure unit has an inclined surface that is inclined with respect to the first surface, and
the inclined surface is a silicon crystal plane of a plane index (111).

(8)

The solid-state imaging device according to (7), in which an inclination angle of the inclined surface with respect to the first surface is 90° or smaller.

(9)

The solid-state imaging device according to any one of (2) to (8), in which a plurality of the protrusions or a plurality of the recesses is arranged to bring the protrusions or the recesses into contact with each other as viewed from the normal direction.

(10)

The solid-state imaging device according to any one of (2) to (8), in which a plurality of the protrusions or a plurality of the recesses is arranged at intervals as viewed from the normal direction.

(11)

The solid-state imaging device according to any one of (1) to (10), in which a material of the reflective portion is a metal material or a material containing carbon (C).

(12)

The solid-state imaging device according to any one of (1) to (11), further including:
a charge retaining unit that is disposed in a normal direction of the first surface with respect to the photoelectric conversion unit, and retains the electric charge transferred from the photoelectric conversion unit; and
a transfer transistor that transfers the electric charge generated by the photoelectric conversion unit, from the photoelectric conversion unit to the charge retaining unit,
in which the reflective portion includes a first reflective portion that is disposed to overlap the transfer transistor, and is provided to extend substantially parallel to the first surface, as viewed from the normal direction.

(13)

The solid-state imaging device according to any one of (1) to (12), further including:
a charge retaining unit that is disposed in a normal direction of the first surface with respect to the photoelectric conversion unit, and retains the electric charge transferred from the photoelectric conversion unit; and
a transfer transistor that transfers the electric charge generated by the photoelectric conversion unit, from the photoelectric conversion unit to the charge retaining unit,
in which the reflective portion includes a second reflective portion that is disposed at a position different from the transfer transistor, and is provided to extend substantially parallel to the first surface, as viewed from the normal direction.

(14)

The solid-state imaging device according to any one of (1) to (13), further including
a charge retaining unit that is disposed in a normal direction of the first surface with respect to the photoelectric conversion unit, and retains the electric charge transferred from the photoelectric conversion unit,
in which the reflective portion includes a third reflective portion that is disposed between the photoelectric conversion unit and the charge retaining unit, and is provided so as to extend substantially parallel to the first surface.

(15)

A method for manufacturing a solid-state imaging device, the method including:
forming a photoelectric conversion unit in a semiconductor substrate having a first surface as a light receiving surface, the photoelectric conversion unit being configured to perform photoelectric conversion to generate electric charge corresponding to an amount of received light; and
forming a reflective portion that is provided in the semiconductor substrate so as to extend substantially parallel to the first surface and reflects light that has passed through the first surface, and forming an uneven structure unit in the first surface.

(16)

The method according to (15), in which
the forming the uneven structure unit includes:
forming a first mask material on the first surface;
forming a second mask material on the first mask material;
forming, in the second mask material, a pattern having at least one trench inclined with respect to a pixel array direction, as viewed from a normal direction of the first surface;
processing the first mask material and the semiconductor substrate, using the second mask material as a mask; and
processing the semiconductor substrate, using the first mask material as a mask.

Aspects of the present disclosure are not limited to the above-described individual embodiments, but include various modifications that can be conceived by those skilled in the art, and the effects of the present disclosure are not limited to the effects described above either. That is, various additions, modifications, and partial deletions are possible without departing from the conceptual idea and spirit of the present disclosure derived from the matters defined in the claims and equivalents thereof.

### REFERENCE SIGNS LIST

11 Semiconductor substrate
11B Back surface
11C Uneven structure unit
11C1 Protrusion
51 Photoelectric conversion unit
101 Imaging device
121 Sensor pixel
12 Second light blocking unit
12H Horizontal light blocking portion
13 First light blocking unit
13H Horizontal light blocking portion
13V Vertical light blocking portion
L Incident light
20 Element isolating portion
20H Horizontal light blocking portion
TRM Trench

1. A solid-state imaging device comprising:
a semiconductor substrate including a first surface as a light receiving surface, and an uneven structure unit provided in the first surface;
a photoelectric conversion unit that is provided in the semiconductor substrate, and performs photoelectric conversion to generate electric charge corresponding to an amount of received light; and
a reflective portion that is provided in the semiconductor substrate so as to extend substantially parallel to the first surface, and reflects light that has passed through the first surface.

2. The solid-state imaging device according to claim 1, wherein
the uneven structure unit includes a plurality of protrusions or a plurality of recesses, and
the protrusions or the recesses have a substantially polygonal outer shape as viewed from a normal direction of the first surface.

3. The solid-state imaging device according to claim 2, wherein at least one side of the outer shape of the protrusion or the recess as viewed from the normal direction is inclined with respect to a pixel array direction.

4. The solid-state imaging device according to claim 3, wherein
the protrusion or the recess has a shape of a substantially quadrangular pyramid, and
four sides of the outer shape of the protrusion or the recess as viewed from the normal direction are inclined by 45° with respect to the pixel array direction.

5. The solid-state imaging device according to claim 3, wherein the protrusion or the recess has a shape of a substantially hexagonal pyramid.

6. The solid-state imaging device according to claim 3, wherein the pixel array direction is a direction in which an element isolating portion that isolates a plurality of pixels extends.

7. The solid-state imaging device according to claim 3, wherein
the semiconductor substrate is a silicon substrate,
the uneven structure unit has an inclined surface that is inclined with respect to the first surface, and
the inclined surface is a silicon crystal plane of a plane index (111).

8. The solid-state imaging device according to claim 7, wherein an inclination angle of the inclined surface with respect to the first surface is not greater than 90°.

9. The solid-state imaging device according to claim 2, wherein a plurality of the protrusions or a plurality of the recesses is arranged to bring the protrusions or the recesses into contact with each other, as viewed from the normal direction.

10. The solid-state imaging device according to claim 2, wherein a plurality of the protrusions or a plurality of the recesses is arranged at intervals as viewed from the normal direction.

11. The solid-state imaging device according to claim 1, wherein a material of the reflective portion is a metal material or a material containing carbon (C).

12. The solid-state imaging device according to claim 1, further comprising:
a charge retaining unit that is disposed in a normal direction of the first surface with respect to the photoelectric conversion unit, and retains the electric charge transferred from the photoelectric conversion unit; and
a transfer transistor that transfers the electric charge generated by the photoelectric conversion unit, from the photoelectric conversion unit to the charge retaining unit,
wherein the reflective portion includes a first reflective portion that is disposed to overlap the transfer transistor, and is provided to extend substantially parallel to the first surface, as viewed from the normal direction.

13. The solid-state imaging device according to claim 1, further comprising:
a charge retaining unit that is disposed in a normal direction of the first surface with respect to the photoelectric conversion unit, and retains the electric charge transferred from the photoelectric conversion unit; and
a transfer transistor that transfers the electric charge generated by the photoelectric conversion unit, from the photoelectric conversion unit to the charge retaining unit,
wherein the reflective portion includes a second reflective portion that is disposed at a position different from the transfer transistor, and is provided to extend substantially parallel to the first surface, as viewed from the normal direction.

14. The solid-state imaging device according to claim 1, further comprising
a charge retaining unit that is disposed in a normal direction of the first surface with respect to the photoelectric conversion unit, and retains the electric charge transferred from the photoelectric conversion unit,
wherein the reflective portion includes a third reflective portion that is disposed between the photoelectric conversion unit and the charge retaining unit, and is provided so as to extend substantially parallel to the first surface.

15. A method for manufacturing a solid-state imaging device, the method comprising:
forming a photoelectric conversion unit in a semiconductor substrate having a first surface as a light receiving surface, the photoelectric conversion unit being configured to perform photoelectric conversion to generate electric charge corresponding to an amount of received light; and
forming a reflective portion that is provided in the semiconductor substrate so as to extend substantially parallel to the first surface and reflects light that has passed through the first surface, and forming an uneven structure unit in the first surface.

16. The method according to claim 15, wherein
the forming the uneven structure unit includes:
forming a first mask material on the first surface;
forming a second mask material on the first mask material;
forming, in the second mask material, a pattern having at least one trench inclined with respect to a pixel array direction, as viewed from a normal direction of the first surface;
processing the first mask material and the semiconductor substrate, using the second mask material as a mask; and
processing the semiconductor substrate, using the first mask material as a mask.
